(19) United States
(12) Patent Application Publication
(10) Pub. No.: US 2026/0033100 A1
(43) Pub. Date: Jan. 29, 2026

(54) DISPLAY DEVICE AND ELECTRONIC DEVICE INCLUDING THE SAME

(71) Applicant: SAMSUNG DISPLAY CO., LTD., YONGIN-SI (KR)

(72) Inventors: KANG SAN KIM, YONGIN-SI (KR); NAK CHO CHOI, YONGIN-SI (KR); BEOM YEOL PARK, YONGIN-SI (KR)

(21) Appl. No.: 19/056,980

(22) Filed: Feb. 19, 2025

(30) Foreign Application Priority Data
Jul. 25, 2024 (KR) 10-2024-0098454

(51) Int. Cl. H10H 29/855; H01L 25/075; H10H 29/37

(52) U.S. Cl. CPC H10H 29/855; H01L 25/0753; H10H 29/37; H10H 29/8552

(57) ABSTRACT

A display device includes: a substrate; a first anode electrode, a second anode electrode, and a third anode electrode disposed adjacent to each other on the substrate; a pixel defining layer disposed on the anode electrodes, defining a first, second and third emission areas corresponding to each electrode; a first refractive layer having a groove, and disposed on the pixel defining layer to overlap the first emission area, the second emission area, and the third emission area; and a second refractive layer disposed in the groove of the first refractive layer, and having a refractive index different from that of the first refractive layer. The groove overlaps the first and second emission areas, the second refractive layer disposed in the groove overlaps the first and second emission areas, and each of the groove and the second refractive layer in the groove has a width that gradually decreases toward the substrate.

### CROSS-REFERENCE TO RELATED APPLICATION

This patent application claims priority under 35 U.S.C. 119 to Korean Patent Application No. 10-2024-0098454 filed on Jul. 25, 2024 in the Korean Intellectual Property Office, the disclosure of which is incorporated by reference in its entirety.

### 1. TECHNICAL FIELD

The present disclosure is directed to a display device, and more particularly, to a display device capable of adjusting its viewing angle and an electronic device including the same.

### 2. DISCUSSION OF RELATED ART

Limited viewing angles in display devices pose significant challenges in various settings, particularly in vehicles, where the need for clear visibility is crucial for safety and functionality. Traditional displays, such as liquid crystal display (LCDs) and light emitting diode element (LED) panels, often suffer from narrow optimal viewing angles, leading to color shifts, brightness variations, and loss of image clarity when viewed from the side. This is especially problematic in automotive environments where drivers and passengers may need to view display information from different positions across the cabin. For instance, a driver needs to see navigation details clearly without shifting focus from the road, while passengers may want to view media or control interfaces from the passenger seat. If the display cannot provide consistent visibility across these different viewing angles, the utility and safety of the technology are compromised, potentially leading to distractions or a lack of access to important vehicle functions or information.

The prior art has attempted to address these issues through various technological improvements, but many solutions still fall short in dynamic environments such as vehicles. For example, enhanced backlighting and pixel design have been used to broaden viewing angles on some displays, yet these enhancements often do not fully solve visibility issues at more acute angles. This is particularly evident during daylight driving when sunlight can wash out display images or create reflections that obscure critical information. Additionally, the fixed nature of most vehicle displays means that they cannot adapt to the changing positions of occupants or the varying light conditions that characterize different times of day and different driving environments. As a result, there remains a clear need for a display technology that not only improves baseline visibility but also dynamically adapts to the specific viewing requirements of vehicle occupants, thereby ensuring that all users have access to clear, readable display content regardless of their position in the vehicle or external lighting conditions.

### SUMMARY

Aspects of the present disclosure provide a display device capable of adjusting its viewing angle and an electronic device (e.g., a vehicle) including the same.

According to an embodiment of the present disclosure, there is provided a display device including: a substrate; a first anode electrode, a second anode electrode, and a third anode electrode, the second anode electrode disposed adjacent to the first and second anode electrodes on the substrate; a pixel defining layer disposed on the first anode electrode, the second anode electrode, and the third anode electrode, and defining a first emission area overlapping the first anode electrode, a second emission area overlapping the second anode electrode, and a third emission area overlapping the third anode electrode; a first refractive layer having a groove, and disposed on the pixel defining layer to overlap the first emission area, the second emission area, and the third emission area; and a second refractive layer disposed in the groove of the first refractive layer, and having a refractive index different from that of the first refractive layer. The groove overlaps the first emission area and the second emission area. The second refractive layer disposed in the groove overlaps the first emission area and the second emission area. A width of the groove and the second refractive layer in the groove gradually decreases toward the substrate.

The refractive index of the second refractive layer may be greater than the refractive index of the first refractive layer.

A difference between the refractive index of the first refractive layer and the refractive index of the second refractive layer may be greater than or equal to 0.1.

The refractive index of the first refractive layer may range from 1.4 to 1.5, and the refractive index of the second refractive layer may range from 1.6 to 1.7.

The groove and the second refractive layer in the groove may have the same shape.

In an embodiment, the groove and the second refractive layer in the groove each have a cross-section that is either: (i) triangular and pointed toward the substrate, (ii) parabolic and convex toward the substrate, or (iii) lens-shapes and convex toward the substrate.

The first refractive layer in the groove may include: a first side surface facing one inner wall of the groove; and a second side surface facing the other inner wall of the groove.

A distance between the first side surface and the second side surface may gradually decrease along a direction toward the substrate.

The first side surface of the second refractive layer may overlap the first emission area, and the second side surface of the second refractive layer may overlap the second emission area.

An angle between a first side surface of the second refractive layer and a top surface of the second refractive layer may be an acute angle.

The second refractive layer may include: a flat portion disposed on the first refractive layer; and a protrusion extending from the flat portion and disposed in the groove of the first refractive layer.

The flat portion of the second refractive layer may overlap the first emission area, the second emission area, and the third emission area.

The protrusion of the second refractive layer may overlap the first emission area and the second emission area.

In an embodiment, the protrusion of the second refractive layer does not overlap the third emission area.

The display device may further include a light blocking layer disposed on the first refractive layer.

The light blocking layer may be disposed on the first refractive layer adjacent to the groove.

In a plan view, the light blocking layer may be disposed between the second emission area and the third emission area.

In a plan view, the first emission area and the second emission area may be disposed between two adjacent light blocking layers.

The display device may further include a first light emitting layer disposed on the first anode electrode; a second light emitting layer disposed on the second anode electrode; a third light emitting layer disposed on the third anode electrode; and a common electrode disposed on the first light emitting layer, the second light emitting layer, and the third light emitting layer.

The display device may further include a first light emitting element including the first anode electrode, the first light emitting layer, and the common electrode; a second light emitting element including the second anode electrode, the second light emitting layer, and the common electrode; and a third light emitting element including the third anode electrode, the third light emitting layer, and the common electrode.

In an embodiment, the first light emitting element and the second light emitting element are alternately turned on during a first display mode period, and the third light emitting element is turned on during a second display mode period.

The first display mode period may include a plurality of sub-display periods, the first light emitting element may be turned on in an odd-numbered sub-display period of the sub-display periods, and the second light emitting element may be turned on in an even-numbered sub-display period of the sub-display periods.

First light emitted from the first light emitting element, second light emitted from the second light emitting element, and third light emitted from the third light emitting element may travel in different directions.

The first light may travel in a rightward direction relative to the display device, the second light may travel in a leftward direction relative to the display device, and the third light may travel in a forward direction relative to the display device.

The first light emitting element, the second light emitting element, and the third light emitting element may emit light of the same color.

A size of the third emission area may be larger than a size of the first emission area.

A size of the second emission area may be equal to a size of the first emission area.

At least one of the first refractive layer or the second refractive layer may include a transparent organic material.

The display device may further include a pixel circuit connected to the first light emitting element, the second light emitting element, and the third light emitting element.

The display device may further include a gate line, an emission control line and a data line connected to the pixel circuit.

In an embodiment, the gate line includes an initialization gate line (GIL) receiving an initialization gate signal (GI), a write gate line (GWL) receiving a write gate signal (GW), and a bias gate line (GBL) receiving a bias gate signal (GB), the emission control line includes a first emission control line (EML1) receiving a first emission control signal (EM1), a second emission control line (EML2) receiving a second emission control signal (EM2), and a third emission control line (EML3) receiving a third emission control signal (EM3), and the data line receives a first data voltage, a second data voltage, and a third data voltage.

In an embodiment, the pixel circuit (PC) includes a first transistor (T1) having a gate electrode connected to a first node (N1), a source electrode connected to a second node (N2), and a drain electrode connected to a third node (N3); a second transistor (T2) having a gate electrode connected to the write gate line (GWL), a source electrode connected to the data line (DL), and a drain electrode connected to the second node; a third transistor (T3) having a gate electrode connected to the write gate line, a source electrode connected to the third node, and a drain electrode connected to the first node; a fourth transistor (T4) having a gate electrode connected to the initialization gate line, a source electrode connected to the first node, and a drain electrode connected to an initialization voltage line (VIL); a fifth-first transistor (T5-1) having a gate electrode connected to the first emission control line, a source electrode connected to a driving voltage line, and a drain electrode connected to the second node; a fifth-second transistor (T5-2) having a gate electrode connected to the second emission control line, a source electrode connected to the driving voltage line, and a drain electrode connected to the second node; a fifth-third transistor (T5-3) having a gate electrode connected to the third emission control line, a source electrode connected to the driving voltage line, and a drain electrode connected to the second node; a sixth-first transistor (T6-1) having a gate electrode connected to the first emission control line, a source electrode connected to the third node, and a drain electrode connected to a fourth node; a sixth-second transistor (T6-2) having a gate electrode connected to the second emission control line, a source electrode connected to the third node, and a drain electrode connected to a fifth node; a sixth-third transistor (T6-3) having a gate electrode connected to the third emission control line, a source electrode connected to the third node, and a drain electrode connected to a sixth node; a seventh-first transistor (T7-1) having a gate electrode connected to the bias gate line (GBL), a source electrode connected to the fourth node (N4), and a drain electrode connected to the initialization voltage line (VIL); a seventh-second transistor (T7-2) having a gate electrode connected to the bias gate line, a source electrode connected to the fifth node, and a drain electrode connected to the initialization voltage line; a seventh-third transistor (T7-3) having a gate electrode connected to the bias gate line (GBL), a source electrode connected to the sixth node (N6), and a drain electrode connected to the initialization voltage line; and a capacitor (Cst) connected between the driving voltage line and the first node (N1), wherein the first anode electrode of the first light emitting element is connected to the fourth node, the second anode electrode of the second light emitting element is connected to the fifth node, and the third anode electrode of the third light emitting element is connected to the sixth node.

In an embodiment, in an initialization period (P1) of the odd-numbered sub-display period, the initialization gate signal (GI) has an active level, in a data write period (P2) of the odd-numbered sub-display period, the write gate signal (GW) has an active level, in the data write period (P2) of the odd-numbered sub-display period, a first data voltage (Vd1) is applied to the data line (DL), in a reset period (P3) of the odd-numbered sub-display period, the bias gate signal (GB) has an active level, and in an emission period (P4) of the odd-numbered sub-display period, the first emission control signal (EM1) has an active level.

In an embodiment, in an initialization period (P5) of the even-numbered sub-display period, the initialization gate signal (GI) has an active level, in a data write period (P6) of the even-numbered sub-display period, the write gate signal (GW) has an active level, in the data write period (P6) of the even-numbered sub-display period, a second data voltage (Vd2) is applied to the data line (DL), in a reset period (P7) of the even-numbered sub-display period, the bias gate signal (GB) has an active level, and in an emission period (P8) of the even-numbered sub-display period, the second emission control signal (EM2) has an active level.

In an embodiment, in an initialization period (P1) of the second display mode period, the initialization gate signal (GI) has an active level, and in a data write period (P2) of the second display mode period, the write gate signal (GW) has an active level, in the data write period (P2) of the second display mode period, the third data voltage is applied to the data line, in a reset period (P3) of the second display mode period, the bias gate signal (GB) has an active level, and in an emission period (P4) of the second display mode period, the third emission control signal (EM3) has an active level.

According to an embodiment of the present disclosure, there is provided a vehicle including: a dashboard; a driver seat and a passenger seat disposed adjacent to the dashboard; and a display device disposed on the dashboard. The display device includes: a substrate; a first anode electrode, a second anode electrode, and a third anode electrode, the second anode electrode disposed adjacent to the first and third anode electrodes on the substrate; a pixel defining layer disposed on the first anode electrode, the second anode electrode, and the third anode electrode, and defining a first emission area overlapping the first anode electrode, a second emission area overlapping the second anode electrode, and a third emission area overlapping the third anode electrode; a first light emitting layer disposed on the first anode electrode; a second light emitting layer disposed on the second anode electrode; a third light emitting layer disposed on the third anode electrode; a cathode electrode disposed on the first light emitting layer, the second light emitting layer, and the third light emitting layer; a first light emitting element including the first anode electrode, the first light emitting layer, and the cathode electrode; a second light emitting element including the second anode electrode, the second light emitting layer, and the cathode electrode; and a third light emitting element including the third anode electrode, the third light emitting layer, and the cathode electrode, wherein the display device is configured to control a light emission direction of the first light emitting element, the second light emitting element and the third light emitting element, based on whether the vehicle is being driven.

In an embodiment when the vehicle is driven, the display device alternately turns on the first light emitting element and the second light emitting element, such that first light emitted from the first light emitting element is directed toward the driver seat, and second light emitted from the second light emitting element is directed toward the passenger seat.

The first light and the second light may represent different images.

The first light may represent an image related to vehicle information, and the second light may represent an image related to entertainment information.

In an embodiment when the vehicle is stopped, the display device turns on the third light emitting element, and third light emitted from the third light emitting element is directed toward the driver seat and toward the passenger seat.

The third light may represent an image related to device control information of the vehicle.

The display device further may further include a first refractive layer having a groove, and disposed on the pixel defining layer to overlap the first emission area, the second emission area, and the third emission area; and a second refractive layer disposed in the groove of the first refractive layer, and having a refractive index different from that of the first refractive layer, wherein the groove overlaps the first emission area and the second emission area, the second refractive layer disposed in the groove overlaps the first emission area and the second emission area, and the groove and the second refractive layer in the groove each have a width that gradually decreases toward the substrate.

The display device and a vehicle display device according to an embodiment may have a viewing angle adjustment function. For example, the display device according to an embodiment may be applied to the vehicle, so that different images may be alternately provided to the driver's seat and the passenger seat when the vehicle is driven.

Additionally, according to the display device of an embodiment, when the vehicle is stopped, the same image may be provided to the driver's seat and the passenger seat.

According to an embodiment of the present disclosure, there is provided an electronic device including a processor, a memory, a display device, and a user interface. The memory has stored application programs for execution by the processor. The display device includes a display panel. The display panel includes a first anode electrode, a second anode electrode, and a third anode electrode, the second anode electrode disposed adjacent to the first and third anode electrodes; a pixel defining layer; a first refractive layer; and a second refractive layer disposed. The pixel defining layer us disposed over the first, second, and third anode electrodes, for defining a first emission area overlapping the first anode electrode, a second emission area overlapping the second anode electrode, and a third emission area overlapping the third anode electrode. The first refractive layer has a groove and is disposed over the pixel defining layer. The second refractive layer is disposed within the groove of the first refractive layer. The second refractive layer has a refractive index different from that of the first refractive layer, and both the groove and the second refractive layer taper in width. The user interface is configured to sense user input via touch or cursor select of an icon presented on the display panel, wherein the processor is caused to execute one or more of the stored application programs upon receipt of the user input.

The stored application programs may include one or more of a camera application, an audiovisual streaming application, or a telephone application.

The user interface may be a touch screen embedded in the display panel, wherein the touch screen includes touch sensors for sensing a touch or a tap by a user.

The user interface may include an audio sensor embedded in the display panel, wherein the audio sensor is configured to receive voice commands to cause access to one or more of the application programs.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view of a display device according to an embodiment;

FIG. 2 is a plan view of a display area of FIG. 1;

FIG. 3 is a detailed configuration diagram of a unit pixel of FIG. 2;

FIG. 4 is a cross-sectional view taken along line I-I′ of FIG. 3;

FIG. 5 is a cross-sectional view taken along lines X1-X1′, X2-X2′, X3-X3′, and X4-X4′ of FIG. 3;

FIG. 6 is a perspective view of a first refractive layer, a second refractive layer, and a light blocking layer according to an embodiment;

FIG. 7 and FIG. 8 illustrate the path of light as it travels through the display device of FIG. 4 and FIG. 5;

FIGS. 9, 10, and 11 explain the operation of the display device according to an embodiment;

FIG. 12 illustrates how the first pixel is interconnected with the gate line and the data line of the display device according to an embodiment;

FIG. 13 is a diagram showing an equivalent circuit of the first pixel of FIG. 12;

FIG. 14 is a timing diagram of gate signals, emission control signals, and data voltages in a first display mode period;

FIG. 15 is a timing diagram of gate signals, emission control signals, and data voltages in a second display mode period;

FIGS. 16 to 25 are process cross-sectional views illustrating a method of manufacturing the display device according to an embodiment;

FIG. 26 is a cross-sectional view of the display device according to an embodiment;

FIG. 27 is a cross-sectional view of the display device according to an embodiment;

FIG. 28 is a cross-sectional view of the display device according to an embodiment;

FIGS. 29 and 30 are schematic diagrams illustrating a vehicle including the display device according to an embodiment;

FIG. 31 shows a cross-sectional captured image of the display device according to an embodiment;

FIG. 32 illustrates a simulated experimental image illustrating the light path of the display device according to an embodiment; and

FIG. 33 is a diagram illustrating an electronic device according to an embodiment.

### DETAILED DESCRIPTION

The present invention will now be described more fully hereinafter with reference to the accompanying drawings, in which embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Although the terms “first”, “second”, etc. may be used herein to describe various elements, these elements, are not limited by these terms. These terms may be used to distinguish one element from another element. Thus, a first element discussed below may be termed a second element without departing from teachings of one or more embodiments. The description of an element as a “first” element need not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, various technical interactions and operations are possible. Various embodiments can be practiced individually or in combination.

Hereinafter, exemplary embodiments of the present disclosure will be described with reference to the accompanying drawings.

At least one embodiment pertains to an innovative display device that features a novel arrangement of optical elements to enhance the viewing experience across different viewing angles, particularly suitable for settings like vehicles where visibility from various positions is important. This device includes a substrate upon which three anode electrodes are positioned, defining corresponding emission areas. Over these, a pixel defining layer is applied, topped with a first refractive layer that incorporates a groove spanning across the first and second emission areas. Within this groove lies a second refractive layer, distinguished by its different refractive index and shaped to taper towards the substrate, enhancing the light directing properties of the device. This construction enables the display to dynamically adjust the direction and quality of light emitted, ensuring consistent visibility and image clarity from various angles. This is particularly useful in automotive environments where drivers and passengers require clear and reliable visibility of display information from different positions within the vehicle. The varying widths of the groove and second refractive layer also play a role in optimizing light emission for different viewing angles, making this technology a significant advancement over traditional display systems that struggle with visibility issues at acute angles.

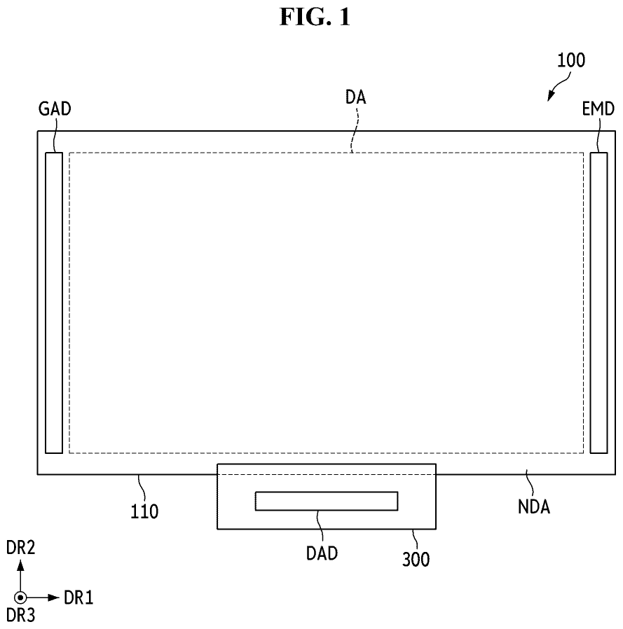

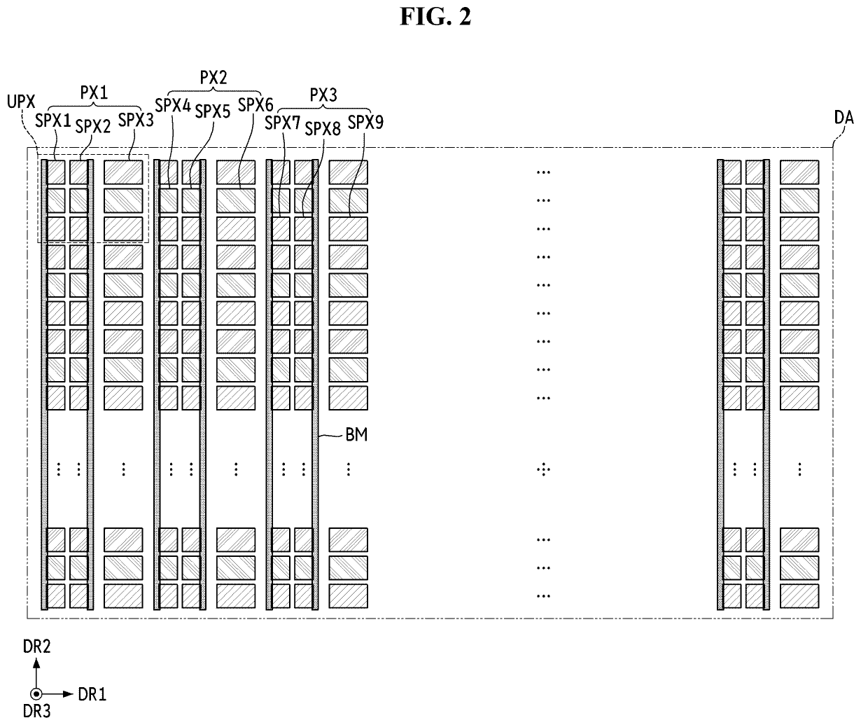

FIG. 1 is a plan view of a display device 100 according to an embodiment, and FIG. 2 is a plan view of a display area of FIG. 1.

Referring to FIG. 1, a display device 100, which is a device for displaying a moving image or a still image, may be used as a display screen of various devices, such as a television, a laptop computer, a monitor, a billboard and an Internet-of-Things (IOT) device, as well as portable electronic devices such as a vehicle display, a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC). However, the display device 100 is not limited to these applications and may be applicable to various other types of electronic devices.

The display device 100 may be a light emitting display device such as an organic light emitting display device including an organic light emitting diode, a quantum dot light emitting display device including a quantum dot light emitting layer, an inorganic light emitting display device including an inorganic semiconductor, or an ultra-small light emitting display device including an ultra-small light emitting diode such as a micro or nano light emitting diode (micro LED or nano LED), but is not limited thereto. For example, the display device 100 may be another type of display device other than a light emitting display device. In the following, embodiments in which the display device 100 is a light emitting display device (e.g., an organic light emitting display device) will be disclosed.

Referring to FIGS. 1 and 2, the display device 100 may include a display panel 110, and a gate driver GAD (e.g., a first driver circuit), an emission driver EMD (e.g., a second driver circuit), and a data driver DAD (e.g., a third driver circuit) that supply driving signals to unit pixels UPX of the display panel 110. The unit pixels UPX may be disposed in a display area DA of a display panel 110. The gate driver GAD and the emission driver EMD may be disposed in a non-display area NDA of the display panel 110. The data driver DAD may be connected to the non-display area NDA of the display panel 110 through a circuit board 300.

The display device 100 may further include a power supply unit (e.g., a power supply) and a timing controller (e.g., a controller circuit). The power supply unit may supply power voltages to the unit pixels UPX, the gate driver GAD, the emission driver EMD, and the data driver DAD. The timing controller may control the operation of the gate driver GAD, the emission driver EMD, and the data driver DAD.

The display panel 110 may have a rectangular shape in a plan view. Although FIGS. 1 and 2 illustrate the display panel 110 with its horizontal length longer than its vertical length, the shape of the display panel 110 is not limited thereto. For example, the display panel 110 may have a shape with its vertical length greater than a horizontal length, a square shape, or the like. The display panel 110 may include an angled corner or a rounded corner.

The planar shape of the display panel 110 is not limited to the illustrated quadrilateral shape, and it may be applied in other shapes. For example, the display panel 110 may have a non-quadrilateral polygonal shape, a circular shape, an elliptical shape, an atypical shape, or another shape in a plan view.

The display panel 110 may be provided as a rigid panel so as not to be substantially transformed, or as a flexible panel that can be transformed to be at least partially folded, bent, or rolled. The display panel 110 may be provided to the display device 100 without bending, or may be provided to the display device 100 while being partially bent.

The display panel 110 may include a display area DA and the non-display area NDA.

A plurality of unit pixels UPX may be disposed in the display area DA. The unit pixel UPX may include a first pixel PX1, a second pixel PX2, and a third pixel PX3 that provide light of different colors (or different wavelengths).

The first pixel PX1, the second pixel PX2, and the third pixel PX3 of the unit pixel UPX may be disposed along a second direction DR2. The first pixel PX1, the second pixel PX2, and the third pixel PX3 of the unit pixel UPX may be disposed adjacent to each other. For example, the first pixel PX1, the second pixel PX2, and the third pixel PX3 of the unit pixel UPX may be disposed adjacent to each other in the second direction DR2. The second pixel PX2 may be disposed between the first pixel PX1 and the third pixel PX3.

The first pixel PX1 may provide light of a first color (e.g., red), the second pixel PX2 may provide light of a second color (e.g., green), and the third pixel PX3 may provide light of a third color (e.g., blue).

The first pixel PX1 may include a first sub-pixel SPX1, a second sub-pixel SPX2, and a third sub-pixel SPX3 disposed adjacent to each other. The first sub-pixel SPX1, the second sub-pixel SPX2, and the third sub-pixel SPX3 may be disposed along a direction (e.g., a first direction DR1) perpendicular to the arrangement direction (e.g., the second direction DR2) of the pixels PX1, PX2, and PX3 included in one unit pixel UPX. The first sub-pixel SPX1, the second sub-pixel SPX2, and the third sub-pixel SPX3 may be disposed adjacent to each other in the first direction DR1. The second sub-pixel SPX2 may be disposed between the first sub-pixel SPX1 and the third sub-pixel SPX3. The sub-pixels of the first pixel PX1 may provide light of the same first color. For example, the first sub-pixel SPX1, the second sub-pixel SPX2, and the third sub-pixel SPX3 may each provide red light. According to an embodiment, at least two of the sub-pixels of the first pixel PX1 have different sizes. For example, among the sub-pixels of the first pixel PX1, the third sub-pixel SPX3 may have the largest area. Meanwhile, the first sub-pixel SPX1 and the second sub-pixel SPX2 may have the same size. According to an embodiment, a distance between the first sub-pixel SPX1 and the second sub-pixel SPX2 us different from a distance between the second sub-pixel SPX2 and the third sub-pixel SPX3. For example, the distance between the second sub-pixel SPX2 and the third sub-pixel SPX3 may be greater than the distance between the first sub-pixel SPX1 and the second sub-pixel SPX2.

The second pixel PX2 may include a fourth sub-pixel SPX4, a fifth sub-pixel SPX5, and a sixth sub-pixel SPX6 disposed adjacent to each other. The fourth sub-pixel SPX4, the fifth sub-pixel SPX5, and the sixth sub-pixel SPX6 may be disposed along a direction (e.g., the first direction DR1) perpendicular to the arrangement direction (e.g., the second direction DR2) of the pixels PX1, PX2, and PX3 included in one unit pixel UPX. The fourth sub-pixel SPX4, the fifth sub-pixel SPX5, and the sixth sub-pixel SPX6 may be disposed adjacent to each other in the first direction DR1. The fifth sub-pixel SPX5 may be disposed between the fourth sub-pixel SPX4 and the sixth sub-pixel SPX6. The sub-pixels of the second pixel PX2 may provide light of the same second color. For example, the fourth sub-pixel SPX4, the fifth sub-pixel SPX5, and the sixth sub-pixel SPX6 may each provide green light. According to an embodiment, at least two of the sub-pixels of the second pixel PX2 have different sizes. For example, among the sub-pixels of the second pixel PX2, the sixth sub-pixel SPX6 may have the largest area. Meanwhile, the fourth sub-pixel SPX4 and the fifth sub-pixel SPX5 may have the same size. According to an embodiment, a distance between the fourth sub-pixel SPX4 and the fifth sub-pixel SPX5 is different from a distance between the fifth sub-pixel SPX5 and the sixth sub-pixel SPX6. For example, the distance between the fifth sub-pixel SPX5 and the sixth sub-pixel SPX6 may be greater than the distance between the fourth sub-pixel SPX4 and the fifth sub-pixel SPX5.

The third pixel PX3 may include a seventh sub-pixel SPX7, an eighth sub-pixel SPX8, and a ninth sub-pixel SPX9 disposed adjacent to each other. The seventh sub-pixel SPX7, the eighth sub-pixel SPX8, and the ninth sub-pixel SPX9 may be disposed along a direction (e.g., the first direction DR1) perpendicular to the arrangement direction (e.g., the second direction DR2) of the pixels PX1, PX2 and PX3 included in one unit pixel UPX. The seventh sub-pixel SPX7, the eighth sub-pixel SPX8, and the ninth sub-pixel SPX9 may be disposed adjacent to each other in the first direction DR1. The eighth sub-pixel SPX8 may be disposed between the seventh sub-pixel SPX7 and the ninth sub-pixel SPX9. In an embodiment, the sub-pixels of the third pixel PX3 provide light of the same third color. For example, the seventh sub-pixel SPX7, the eighth sub-pixel SPX8, and the ninth sub-pixel SPX9 may each provide blue light. According to an embodiment, at least two of the sub-pixels of the third pixel PX3 have different sizes. For example, among the sub-pixels of the third pixel PX3, the ninth sub-pixel SPX9 may have the largest area. Meanwhile, the seventh sub-pixel SPX7 and the eighth sub-pixel SPX8 may have the same size. According to an embodiment, a distance between the seventh sub-pixel SPX7 and the eighth sub-pixel SPX8 is different from a distance between the eighth sub-pixel SPX8 and the ninth sub-pixel SPX9. For example, the distance between the eighth sub-pixel SPX8 and the ninth sub-pixel SPX9 may be greater than the distance between the seventh sub-pixel SPX7 and the eighth sub-pixel SPX8.

In the same unit pixel UPX, the first sub-pixel SPX1 of the first pixel PX1, the fourth sub-pixel SPX4 of the second pixel PX2, and the seventh sub-pixel SPX7 of the third pixel PX3 may be disposed along the second direction DR2. For example, the first sub-pixel SPX1, the fourth sub-pixel SPX4, and the seventh sub-pixel SPX7 of the same unit pixel UPX may be disposed along the second direction DR2.

In the same unit pixel UPX, the second sub-pixel SPX2 of the first pixel PX1, the fifth sub-pixel SPX5 of the second pixel PX2, and the eighth sub-pixel SPX8 of the third pixel PX3 may be disposed along the second direction DR2. For example, the second sub-pixel SPX2, the fifth sub-pixel SPX5, and the eighth sub-pixel SPX8 of the same unit pixel UPX may be disposed along the second direction DR2.

In the same unit pixel UPX, the third sub-pixel SPX3 of the first pixel PX1, the sixth sub-pixel SPX6 of the second pixel PX2, and the ninth sub-pixel SPX9 of the third pixel PX3 may be disposed along the second direction DR2. For example, the third sub-pixel SPX3, the sixth sub-pixel SPX6, and the ninth sub-pixel SPX9 of the same unit pixel UPX may be disposed along the second direction DR2.

In an embodiment, the first sub-pixel SPX1, the second sub-pixel SPX2, the fourth sub-pixel SPX4, the fifth sub-pixel SPX5, the seventh sub-pixel SPX7, and the eighth sub-pixel SPX8 have the same size.

In an embodiment, the third sub-pixel SPX3, the sixth sub-pixel SPX6, and the ninth sub-pixel SPX9 have the same size.

The first sub-pixel SPX1, the second sub-pixel SPX2, the fourth sub-pixel SPX4, the fifth sub-pixel SPX5, the seventh sub-pixel SPX7, and the eighth sub-pixel SPX8 may be sub-pixels having relatively narrow viewing angles in the corresponding pixels. For example, each viewing angle of the first sub-pixel SPX1 and the second sub-pixel SPX2 may be smaller than the viewing angle of the third sub-pixel SPX3, each viewing angle of the fourth sub-pixel SPX4 and the fifth sub-pixel SPX5 may be smaller than the viewing angle of the sixth sub-pixel SPX6, and each viewing angle of the seventh sub-pixel SPX7 and the eighth sub-pixel SPX8 may be smaller than the viewing angle of the ninth sub-pixel SPX9.

The third sub-pixel SPX3, the sixth sub-pixel SPX6, and the ninth sub-pixel SPX9 may be sub-pixels having relatively wide viewing angles in the corresponding pixels. For example, the viewing angle of the third sub-pixel SPX3 may be wider than each viewing angle of the first sub-pixel SPX1 and the second sub-pixel SPX2, the viewing angle of the sixth sub-pixel SPX6 may be wider than each viewing angle of the fourth sub-pixel SPX4 and the fifth sub-pixel SPX5, and the viewing angle of the ninth sub-pixel SPX9 may be wider than each viewing angle of the seventh sub-pixel SPX7 and the eighth sub-pixel SPX8.

A plurality of sub-pixels SPX1 to SPX9 may be connected to gate lines, emission control lines, data lines, and power lines. According to an embodiment, a plurality of sub-pixels disposed along the first direction DR1 in the same row may be connected to the same gate line. For example, the first sub-pixel SPX1, the second sub-pixel SPX2, and the third sub-pixel SPX3 disposed in the same row may be connected to the same gate line. According to an embodiment, a plurality of sub-pixels disposed along the second direction DR2 in the same column may be connected to the same data line. For example, the first sub-pixel SPX1, the fourth sub-pixel SPX4, and the seventh sub-pixel SPX7 disposed in the same column may be connected to the same data line. In an embodiment, sub-pixels of the same pixel are connected to the same data line. For example, the first sub-pixel SPX1, the second sub-pixel SPX2, and the third sub-pixel SPX3 of the first pixel PX1 may be connected to the same data line.

The non-display area NDA may be disposed around the display area DA. In an embodiment, the non-display area NDA surrounds the display area DA.

The display area DA may have various shapes. For example, the display area DA may have a quadrilateral shape, a non-quadrilateral polygonal shape, a circular shape, an elliptical shape, an atypical shape, or another shape. In an embodiment, the display area DA has a shape conforming to the shape of the display panel 110.

The gate driver GAD and the emission driver EMD may be disposed in the non-display area NDA. For example, the gate driver GAD may be disposed in the non-display area NDA (e.g., a left non-display area) positioned on the left side of the display area DA, and the emission driver EMD may be disposed in the non-display area NDA (e.g., a right non-display area) positioned on the right side of the display area DA.

The gate driver GAD may drive the gate lines. For example, the gate driver GAD may supply gate signals to the gate lines. The gate lines may be connected to the gate driver GAD.

The emission driver EMD may drive emission control lines. For example, the emission driver EMD may supply emission control signals to the emission control lines. The emission control lines may be connected to the emission driver EMD.

The circuit board 300 may be electrically connected to the display panel 110, as shown in FIG. 1. In an embodiment, the circuit board 300 may be connected to at least one of the timing controller or the power supply unit through another circuit board, connector, or the like. In an embodiment, the circuit board 300 may be a flexible film such as a flexible printed circuit board (FPCB), a printed circuit board (PCB), or a chip on film (COF), but is not limited thereto.

According to an embodiment, in a plan view as illustrated in FIG. 2, a light blocking layer BM is disposed between the sub-pixels. For example, the light blocking layer BM may be disposed between the second sub-pixel SPX2 and the third sub-pixel SPX3, between the fifth sub-pixel SPX5 and the sixth sub-pixel SPX6, and between the eighth sub-pixel SPX8 and the ninth sub-pixel SPX9. According to an embodiment, the light blocking layer BM is disposed between the sub-pixels having different sizes. The light blocking layer BM may extend, for example, along the second direction DR2. In other words, the light blocking layer BM may extend along the arrangement direction (e.g., the second direction DR2) of the first pixel PX1, the second pixel PX2, and the third pixel PX3 of one unit pixel UPX. In an embodiment, at least a portion of the light blocking layer BM overlaps a sub-pixel adjacent to the light blocking layer BM.

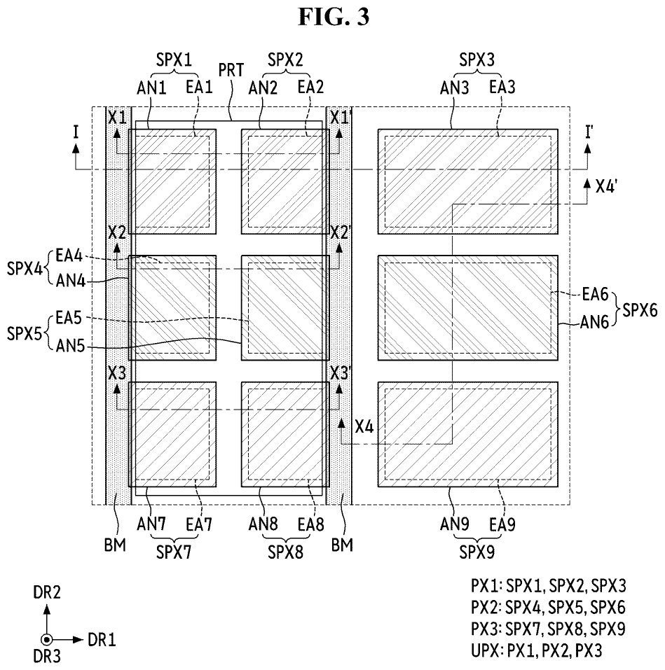

FIG. 3 is a detailed configuration diagram of the unit pixel UPX of FIG. 2 according to an embodiment.

The unit pixel UPX may include the first sub-pixel SPX1, the second sub-pixel SPX2, the third sub-pixel SPX3, the fourth sub-pixel SPX4, the fifth sub-pixel SPX5, the sixth sub-pixel SPX6, the seventh sub-pixel SPX7, the eighth sub-pixel SPX8, and the ninth sub-pixel SPX9, as illustrated in FIG. 3.

The first sub-pixel SPX1 may include a first anode electrode AN1 and a first emission area EA1. In a plan view, an edge of the first anode electrode AN1 may surround the first emission area EA1. For example, the first anode electrode AN1 may entirely surround the first emission area EA1.

The second sub-pixel SPX2 may include a second anode electrode AN2 and a second emission area EA2. In a plan view, an edge of the second anode electrode AN2 may surround the second emission area EA2. For example, the second anode electrode AN2 may entirely surround the second emission area EA2.

The third sub-pixel SPX3 may include a third anode electrode AN3 and a third emission area EA3. In a plan view, an edge of the third anode electrode AN3 may surround the third emission area EA3. For example, the third anode electrode AN3 may entirely surround the third emission area EA3.

The fourth sub-pixel SPX4 may include a fourth anode electrode AN4 and a fourth emission area EA4. In a plan view, an edge of the fourth anode electrode AN4 may surround the fourth emission area EA4. For example, the fourth anode electrode AN4 may entirely surround the fourth emission area EA4.

The fifth sub-pixel SPX5 may include a fifth anode electrode AN5 and a fifth emission area EA5. In a plan view, an edge of the fifth anode electrode AN5 may surround the fifth emission area EA5. For example, the fifth anode electrode AN5 may entirely surround the first emission area EA5.

The sixth sub-pixel SPX6 may include a sixth anode electrode AN6 and a sixth emission area EA6. In a plan view, an edge of the sixth anode electrode AN6 may surround the sixth emission area EA6. For example, the sixth anode electrode AN6 may entirely surround the sixth emission area EA6.

The seventh sub-pixel SPX7 may include a seventh anode electrode AN7 and a seventh emission area EA7. In a plan view, an edge of the seventh anode electrode AN7 may surround the seventh emission area EA7. For example, the seventh anode electrode AN7 may entirely surround the seventh emission area EA7.

The eighth sub-pixel SPX8 may include an eighth anode electrode AN8 and an eighth emission area EA8. In a plan view, an edge of the eighth anode electrode AN8 may surround the eighth emission area EA8. For example, the eighth anode electrode AN8 may entirely surround the eighth emission area EA8.

The ninth sub-pixel SPX9 may include a ninth anode electrode AN9 and a ninth emission area EA9. In a plan view, an edge of the ninth anode electrode AN9 may surround the ninth emission area EA9. For example, the ninth anode electrode AN9 may entirely surround the ninth emission area EA9.

The first anode electrode AN1, the second anode electrode AN2, and the third anode electrode AN3 of the first pixel PX1 may be disposed along the first direction DR1 or in a first row. The first anode electrode AN1, the second anode electrode AN2, and the third anode electrode AN3 may be disposed adjacent to each other in the first direction DR1. The second anode electrode AN2 may be disposed between the first anode electrode AN1 and the third anode electrode AN3. According to an embodiment, at least two of the anode electrodes of the first pixel PX1 have different sizes. For example, among the anode electrodes of the first pixel PX1, the third anode electrode AN3 may have the largest area. Meanwhile, the first anode electrode AN1 and the second anode electrode AN2 may have the same size. According to an embodiment, the distance between the first anode electrode AN1 and the second anode electrode AN2 is different from the distance between the second anode electrode AN2 and the third anode electrode AN3. For example, the distance between the second anode electrode AN2 and the third anode electrode AN3 may be greater than the distance between the first anode electrode AN1 and the second anode electrode AN2.

The fourth anode electrode AN4, the fifth anode electrode AN5, and the sixth anode electrode AN6 of the second pixel PX2 may be disposed along the first direction DR1 or in a second row. The fourth anode electrode AN4, the fifth anode electrode AN5, and the sixth anode electrode AN6 may be disposed adjacent to each other in the first direction DR1. The fifth anode electrode AN5 may be disposed between the fourth anode electrode AN4 and the sixth anode electrode AN6. In an embodiment, at least two of the anode electrodes of the second pixel PX2 have different sizes. For example, among the anode electrodes of the second pixel PX2, the sixth anode electrode AN6 may have the largest area. Meanwhile, the fourth anode electrode AN4 and the fifth anode electrode AN5 may have the same size. In an embodiment, the distance between the fourth anode electrode AN4 and the fifth anode electrode AN5 is different from the distance between the fifth anode electrode AN5 and the sixth anode electrode AN6. For example, the distance between the fifth anode electrode AN5 and the sixth anode electrode AN6 may be greater than the distance between the fourth anode electrode AN4 and the fifth anode electrode AN5.

The seventh anode electrode AN7, the eighth anode electrode AN8, and the ninth anode electrode AN9 of the third pixel PX3 may be disposed along the first direction DR1 or in a third row. The seventh anode electrode AN7, the eighth anode electrode AN8, and the ninth anode electrode AN9 may be disposed adjacent to each other in the first direction DR1. The eighth anode electrode AN8 may be disposed between the seventh anode electrode AN7 and the ninth anode electrode AN9. In an embodiment, at least two of the anode electrodes of the third pixel PX3 have different sizes. For example, among the anode electrodes of the third pixel PX3, the ninth anode electrode AN9 may have the largest area. Meanwhile, the seventh anode electrode AN7 and the eighth anode electrode AN8 may have the same size. According to an embodiment, the distance between the seventh anode electrode AN7 and the eighth anode electrode AN8 is different from the distance between the eighth anode electrode AN8 and the ninth anode electrode AN9. For example, the distance between the eighth anode electrode AN8 and the ninth anode electrode AN9 may be greater than the distance between the seventh anode electrode AN7 and the eighth anode electrode AN8.

In the same unit pixel UPX, the first anode electrode AN1 of the first pixel PX1, the fourth anode electrode AN4 of the second pixel PX2, and the seventh anode electrode AN7 of the third pixel PX3 may be disposed along the second direction DR2 or in a first column. For example, the first anode electrode AN1, the fourth anode electrode AN4, and the seventh anode electrode AN7 of the same unit pixel UPX may be disposed along the second direction DR2.

In the same unit pixel UPX, the second anode electrode AN2 of the first pixel PX1, the fifth anode electrode AN5 of the second pixel PX2, and the eighth anode electrode AN8 of the third pixel PX3 may be disposed along the second direction DR2 or in a second column. For example, the second anode electrode AN2, the fifth anode electrode AN5, and the eighth anode electrode AN8 of the same unit pixel UPX may be disposed along the second direction DR2.

In the same unit pixel UPX, the third anode electrode AN3 of the first pixel PX1, the sixth anode electrode AN6 of the second pixel PX2, and the ninth anode electrode AN9 of the third pixel PX3 may be disposed along the second direction DR2 or in a third column. For example, the third anode electrode AN3, the sixth anode electrode AN6, and the ninth anode electrode AN9 of the same unit pixel UPX may be disposed along the second direction DR2.

In an embodiment, the first anode electrode AN1, the second anode electrode AN2, the fourth anode electrode AN4, the fifth anode electrode AN5, the seventh anode electrode AN7, and the eighth anode electrode AN8 have the same size.

In an embodiment, the third anode electrode AN3, the sixth anode electrode AN6, and the ninth anode electrode AN9 have the same size.

The first emission area EA1, the second emission area EA2, and the third emission area EA3 of the first pixel PX1 may be disposed along the first direction DR1 or in the first row. The first emission area EA1, the second emission area EA2, and the third emission area EA3 may be disposed adjacent to each other in the first direction DR1. The second emission area EA2 may be disposed between the first emission area EA1 and the third emission area EA3. According to an embodiment, at least two of the emission areas of the first pixel PX1 have different sizes. For example, among the emission areas of the first pixel PX1, the third emission area EA3 may have the largest area. Meanwhile, the first emission area EA1 and the second emission area EA2 may have the same size. According to an embodiment, the distance between the first emission area EA1 and the second emission area EA2 is different from the distance between the second emission area EA2 and the third emission area EA3. For example, the distance between the second emission area EA2 and the third emission area EA3 may be greater than the distance between the first emission area EA1 and the second emission area EA2.

The fourth emission area EA4, the fifth emission area EA5, and the sixth emission area EA6 of the second pixel PX2 may be disposed along the first direction DR1 or in the second row. The fourth emission area EA4, the fifth emission area EA5, and the sixth emission area EA6 may be disposed adjacent to each other in the first direction DR1. The fifth emission area EA5 may be disposed between the fourth emission area EA4 and the sixth emission area EA6. In an embodiment, at least two of the emission areas of the second pixel PX2 have different sizes. For example, among the emission areas of the second pixel PX2, the sixth emission area EA6 may have the largest area. Meanwhile, the fourth emission area EA4 and the fifth emission area EA5 may have the same size. In an embodiment, the distance between the fourth emission area EA4 and the fifth emission area EA5 are different from the distance between the fifth emission area EA5 and the sixth emission area EA6. For example, the distance between the fifth emission area EA5 and the sixth emission area EA6 may be greater than the distance between the fourth emission area EA4 and the fifth emission area EA5.

The seventh emission area EA7, the eighth emission area EA8, and the ninth emission area EA9 of the third pixel PX3 may be disposed along the first direction DR1 or in the third row. The seventh emission area EA7, the eighth emission area EA8, and the ninth emission area EA9 may be disposed adjacent to each other in the first direction DR1. The eighth emission area EA8 may be disposed between the seventh emission area EA7 and the ninth emission area EA9. In an embodiment, at least two of the emission areas of the third pixel PX3 have different sizes. For example, among the emission areas of the third pixel PX3, the ninth emission area EA9 may have the largest area. Meanwhile, the seventh emission area EA7 and the eighth emission area EA8 may have the same size. In an embodiment, the distance between the seventh emission area EA7 and the eighth emission area EA8 is different from the distance between the eighth emission area EA8 and the ninth emission area EA9. For example, the distance between the eighth emission area EA8 and the ninth emission area EA9 may be greater than the distance between the seventh emission area EA7 and the eighth emission area EA8.

In the same unit pixel UPX, the first emission area EA1 of the first pixel PX1, the fourth emission area EA4 of the second pixel PX2, and the seventh emission area EA7 of the third pixel PX3 may be disposed along the second direction DR2 or in the first column. For example, the first emission area EA1, the fourth emission area EA4, and the seventh emission area EA7 of the same unit pixel UPX may be disposed along the second direction DR2.

In the same unit pixel UPX, the second emission area EA2 of the first pixel PX1, the fifth emission area EA5 of the second pixel PX2, and the eighth emission area EA8 of the third pixel PX3 may be disposed along the second direction DR2 or in the second column. For example, the second emission area EA2, the fifth emission area EA5, and the eighth emission area EA8 of the same unit pixel UPX may be disposed along the second direction DR2.

In the same unit pixel UPX, the third emission area EA3 of the first pixel PX1, the sixth emission area EA6 of the second pixel PX2, and the ninth emission area EA9 of the third pixel PX3 may be disposed along the second direction DR2 or in the third column. For example, the third emission area EA3, the sixth emission area EA6, and the ninth emission area EA9 of the same unit pixel UPX may be disposed along the second direction DR2.

In an embodiment, the first emission area EA1, the second emission area EA2, the fourth emission area EA4, the fifth emission area EA5, the seventh emission area EA7, and the eighth emission area EA8 have the same size.

In an embodiment, the third emission area EA3, the sixth emission area EA6, and the ninth emission area EA9 have the same size.

According to an embodiment, in a plan view, as illustrated in FIG. 3, the light blocking layer BM is disposed between some of the anode electrodes. For example, the light blocking layer BM may be disposed between the second anode electrode AN2 and the third anode electrode AN3, be disposed between the fifth anode electrode AN5 and the sixth anode electrode AN6, and be disposed between the eighth anode electrode AN8 and the ninth anode electrode AN9. In an embodiment, the light blocking layer BM is disposed between anode electrodes having different sizes. For example, no light blocking layer may be disposed between anode electrodes having the same size. Meanwhile, at least a portion of the light blocking layer BM may overlap the anode electrode that is adjacent to the light blocking layer.

According to an embodiment, in a plan view as illustrated in FIG. 3, the light blocking layer BM is disposed between some of the emission areas. For example, the light blocking layer BM may be disposed between the second emission area EA2 and the third emission area EA3, be disposed between the fifth emission area EA5 and the sixth emission area EA6, and be disposed between the eighth emission area EA8 and the ninth emission area EA9. In an embodiment, the light blocking layer BM may be disposed between emission areas having different sizes. For example, no light blocking layer may be disposed between the emission areas having the same size. Meanwhile, at least a portion of the light blocking layer BM may overlap an emission area adjacent to the light blocking layer BM.

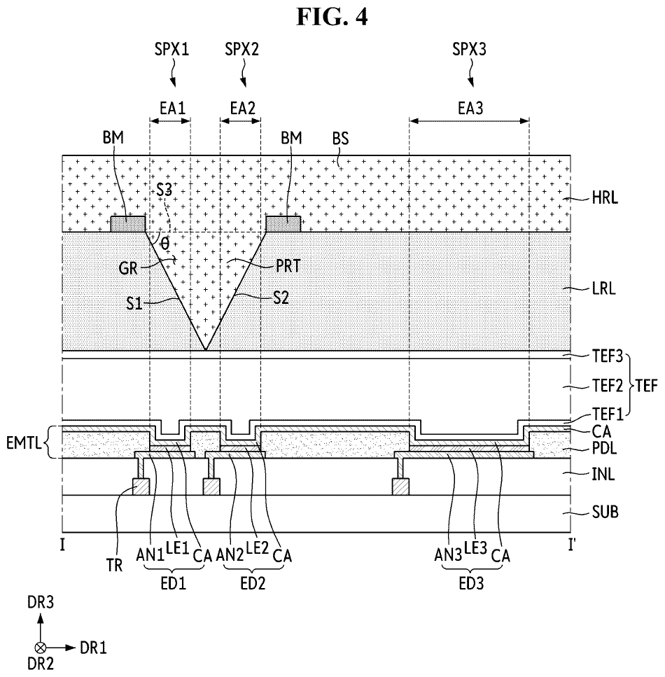

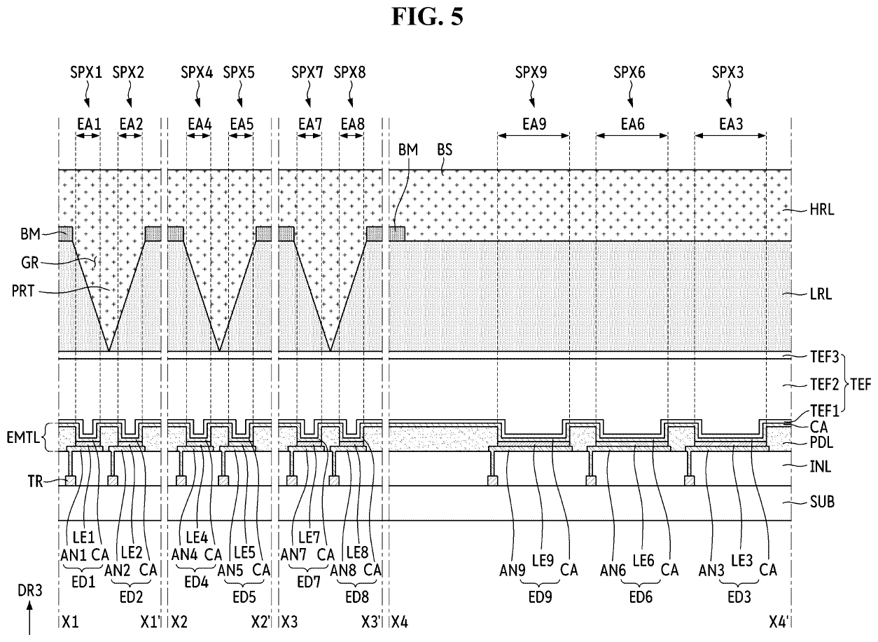

FIG. 4 is a cross-sectional view taken along line I-I′ of FIG. 3, and FIG. 5 is a cross-sectional view taken along lines X1-X1′, X2-X2′, X3-X3′, and X4-X4′ of FIG. 3.

The display device 100 may include a substrate SUB, a transistor TR, an insulating layer INL, a light emitting element layer EMTL, an encapsulation layer TFE, a first refractive layer LRL, the light blocking layer BM, and a second refractive layer HRL in cross-sectional view as illustrated in FIGS. 4 and 5.

The substrate SUB may be a rigid substrate or a flexible substrate which can be bent, folded or rolled. The substrate SUB may be formed of an insulating material such as glass, quartz, or a polymer resin. Examples of the polymer resin include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), or a combination thereof. Alternatively, the substrate SUB may include a metal material.

A panel circuit layer may be disposed on the substrate SUB. For example, a panel circuit layer including circuit elements such as the transistors TR and various signal lines for connecting the circuit elements may be disposed on the substrate.

The insulating layer INL may be disposed on circuit elements such as transistors TR and signal lines. In an embodiment, the insulating layer INL is a planarization film including an organic film. For example, the insulating layer INL may include acrylic resin, epoxy resin, imide resin, ester resin, or the like.

The light emitting element layer EMTL may be disposed on the insulating layer INL. For example, the first to ninth anode electrodes AN1 to AN9 may be disposed on the insulating layer INL. Each anode electrode may be connected to each of the transistors TR (e.g., the drain electrode of each of the transistors TR) through a respective contact hole penetrating the insulating layer INL.

The light emitting element layer EMTL described above may further include a plurality of light emitting elements ED1, ED2, ED3, ED4, ED5, ED6, ED7, ED8, and ED9 and a pixel defining layer PDL, in addition to the first to third anode electrodes AN1 to AN3 described above.

The light emitting elements ED1 to ED9 may include, for example, a first light emitting element ED1 of the first sub-pixel SPX1, a second light emitting element ED2 of the second sub-pixel SPX2, a third light emitting element ED3 of the third sub-pixel SPX3, a fourth light emitting element ED4 of the fourth sub-pixel SPX4, a fifth light emitting element ED5 of the fifth sub-pixel SPX5, a sixth light emitting element ED6 of the sixth sub-pixel SPX6, a seventh light emitting element ED7 of the seventh sub-pixel SPX7, an eighth light emitting element ED8 of the eighth sub-pixel SPX8, and a ninth light emitting element ED9 of the ninth sub-pixel SPX9.

The first light emitting element ED1 may include the first anode electrode AN1, a first light emitting layer LE1, and a cathode electrode CA (e.g., a common electrode). The first light emitting element ED1 may provide light through the first emission area EA1 defined by the pixel defining layer PDL. The first emission area EA1 may represent an area in which the first anode electrode AN1, the first light emitting layer LE1, and the cathode electrode CA are sequentially stacked and holes from the first anode electrode AN1 and electrons from the cathode electrode CA are bonded with each other in the first light emitting layer LE1 to emit light. For example, holes from the first anode electrode AN1 and electrons from the cathode electrode CA combine within the first light emitting layer LE1, resulting in emission of a first light.

The second light emitting element ED2 may include the second anode electrode AN2, a second light emitting layer LE2, and the cathode electrode CA. The second light emitting element ED2 may provide light through the second emission area EA2 defined by the pixel defining layer PDL. The second emission area EA2 may represent an area in which the second anode electrode AN2, the second light emitting layer LE2, and the cathode electrode CA are sequentially stacked and holes from the second anode electrode AN2 and electrons from the cathode electrode CA are bonded with each other in the second light emitting layer LE2 to emit light. For example, holes from the second anode electrode AN2 and electrons from the cathode electrode CA combine within the second light emitting layer LE2, resulting in emission of a second light.

The third light emitting element ED3 may include the third anode electrode AN3, a third light emitting layer LE3, and the cathode electrode CA. The third light emitting element ED3 may provide light through the third emission area EA3 defined by the pixel defining layer PDL. The third emission area EA3 may represent an area in which the third anode electrode AN3, the third light emitting layer LE3, and the cathode electrode CA are sequentially stacked and holes from the third anode electrode AN3 and electrons from the cathode electrode CA are bonded with each other in the third light emitting layer LE3 to emit light. For example, holes from the third anode electrode AN3 and electrons from the cathode electrode CA combine within the third light emitting layer LE3, resulting in emission of a third light.

The fourth light emitting element ED4 may include the fourth anode electrode AN4, a fourth light emitting layer LE4, and the cathode electrode CA. The fourth light emitting element ED4 may provide light through the fourth emission area EA4 defined by the pixel defining layer PDL. The fourth emission area EA4 may represent an area in which the fourth anode electrode AN4, the fourth light emitting layer LE4, and the cathode electrode CA are sequentially stacked and holes from the fourth anode electrode AN4 and electrons from the cathode electrode CA are bonded with each other in the fourth light emitting layer LE4 to emit light. For example, holes from the fourth anode electrode AN4 and electrons from the cathode electrode CA combine within the fourth light emitting layer LE4, resulting in emission of a fourth light.

The fifth light emitting element ED5 may include the fifth anode electrode AN5, a fifth light emitting layer LE5, and the cathode electrode CA. The fifth light emitting element ED5 may provide light through the fifth emission area EA5 defined by the pixel defining layer PDL. The fifth emission area EA5 may represent an area in which the fifth anode electrode AN5, the fifth light emitting layer LE5, and the cathode electrode CA are sequentially stacked and holes from the fifth anode electrode AN5 and electrons from the cathode electrode CA are bonded with each other in the fifth light emitting layer LE5 to emit light. For example, holes from the fifth anode electrode AN5 and electrons from the cathode electrode CA combine within the fifth light emitting layer LE5, resulting in emission of a fifth light.

The sixth light emitting element ED6 may include the sixth anode electrode AN6, a sixth light emitting layer LE6, and the cathode electrode CA. The sixth light emitting element ED6 may provide light through the sixth emission area EA6 defined by the pixel defining layer PDL. The sixth emission area EA6 may represent an area in which the sixth anode electrode AN6, the sixth light emitting layer LE6, and the cathode electrode CA are sequentially stacked and holes from the sixth anode electrode AN6 and electrons from the cathode electrode CA are bonded with each other in the sixth light emitting layer LE6 to emit light. For example, holes from the sixth anode electrode AN6 and electrons from the cathode electrode CA combine within the sixth light emitting layer LE6, resulting in emission of a sixth light.

The seventh light emitting element ED7 may include the seventh anode electrode AN7, a seventh light emitting layer LE7, and the cathode electrode CA. The seventh light emitting element ED7 may provide light through the seventh emission area EA7 defined by the pixel defining layer PDL. The seventh emission area EA7 may represent an area in which the seventh anode electrode AN7, the seventh light emitting layer LE7, and the cathode electrode CA are sequentially stacked and holes from the seventh anode electrode AN7 and electrons from the cathode electrode CA are bonded with each other in the seventh light emitting layer LE7 to emit light. For example, holes from the seventh anode electrode AN7 and electrons from the cathode electrode CA combine within the third light emitting layer LE7, resulting in emission of a seventh light.

The eighth light emitting element ED8 may include the eighth anode electrode AN8, an eighth light emitting layer LE8, and the cathode electrode CA. The eighth light emitting element ED8 may provide light through the eighth emission area EA8 defined by the pixel defining layer PDL. The eighth emission area EA8 may represent an area in which the eighth anode electrode AN8, the eighth light emitting layer LE8, and the cathode electrode CA are sequentially stacked and holes from the eighth anode electrode AN8 and electrons from the cathode electrode CA are bonded with each other in the eighth light emitting layer LE8 to emit light. For example, holes from the eighth anode electrode AN8 and electrons from the cathode electrode CA combine within the third light emitting layer LE8, resulting in emission of an eighth light.

The ninth light emitting element ED9 may include the ninth anode electrode AN9, a ninth light emitting layer LE9, and the cathode electrode CA. The ninth light emitting element ED9 may provide light through the ninth emission area EA9 defined by the pixel defining layer PDL. The ninth emission area EA9 may represent an area in which the ninth anode electrode AN9, the ninth light emitting layer LE9, and the cathode electrode CA are sequentially stacked and holes from the ninth anode electrode AN9 and electrons from the cathode electrode CA are bonded with each other in the ninth light emitting layer LE9 to emit light. For example, holes from the ninth anode electrode AN9 and electrons from the cathode electrode CA combine within the ninth light emitting layer LE9, resulting in emission of a ninth light.

In a top emission structure that emits light toward the cathode electrode CA with respect to the light emitting layer (e.g., the first light emitting layer LE1), the anode electrode (e.g., the first anode electrode AN1) may be formed of a single layer of molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and ITO, an APC alloy, or a stacked structure (ITO/APC/ITO) of APC alloy and ITO to increase reflectivity. The APC alloy may be an alloy of silver (Ag), palladium (Pd) and copper (Cu).

The pixel defining layer PDL may define the first to ninth emission areas EA1 to EA9 of the first to ninth sub-pixels SPX1 to SPX9. To this end, the pixel defining layer PDL may be disposed on the insulating layer INL to expose a partial area of the first anode electrode AN1, a partial area of the second anode electrode AN2, a partial area of the third anode electrode AN3, a partial area of the fourth anode electrode AN4, a partial area of the fifth anode electrode AN5, a partial area of the sixth anode electrode AN6, a partial area of the seventh anode electrode AN7, a partial area of the eighth anode electrode AN8, and a partial area of the ninth anode electrode AN9. For example, the pixel defining layer PDL may include holes to expose these partial areas. The pixel defining layer PDL may cover an edge of the first anode electrode AN1, an edge of the second anode electrode AN2, an edge of the third anode electrode AN3, an edge of the fourth anode electrode AN4, an edge of the fifth anode electrode AN5, an edge of the sixth anode electrode AN6, an edge of the seventh anode electrode AN7, an edge of the eighth anode electrode AN8, and an edge of the ninth anode electrode AN9. For example, the pixel defining layer PDL may cover left and right edges of the anode electrodes but expose central portions of the anode electrodes between the left and right edges. The pixel defining layer PDL may be formed of an organic film such as acryl resin, epoxy resin, phenolic resin, polyamide resin, polyimide resin and the like.

A spacer may be disposed on the pixel defining layer PDL. The spacer may serve to support a mask during a process of manufacturing the first to third light emitting layers LE1 to LE3. The spacer may be formed of an organic layer such as acryl resin, epoxy resin, phenolic resin, polyamide resin, polyimide resin and the like.

The light emitting layers LE1 to LE9 may be formed on the anode electrodes AN1 and AN9, respectively. The first light emitting layer LE1 may include an organic material to emit light in a predetermined color. For example, the first light emitting layer LE1 may include a hole transporting layer, an organic material layer, and an electron transporting layer. The organic material layer may include a host and a dopant. The organic material layer may include a material that emits predetermined light, and may be formed using a phosphorescent material or a fluorescent material. According to an embodiment, the second light emitting layer LE2, the third light emitting layer LE3, the fourth light emitting layer LE4, the fifth light emitting layer LE5, the sixth light emitting layer LE6, the seventh light emitting layer LE7, the eighth light emitting layer LE8, and the ninth light emitting layer LE9 may also have the same configuration as the first light emitting layer LE1 described above.

For example, the organic material layer of the first light emitting layer LE1 in the first emission area EA1 emitting the light of the first color (e.g., red) may include a phosphorescent material including a host material including carbazole biphenyl (CBP) or mCP (1,3-bis(carbazol-9-yl), and a dopant. The dopant may include at least one of PIQIr (acac) (bis(1-phenylisoquinoline) acetylacetonate iridium), PQIr (acac) (bis(1-phenylquinoline) acetylacetonate iridium), PQIr(tris(1-phenylquinoline)iridium)) and PtOEP (octacthylporphyrin platinum). Alternatively, the organic material layer of the first light emitting layer LE1 of the first emission area EA1 may be a fluorescent material including PBD:Eu (DBM) 3 (Phen) or Perylene, but the present disclosure is not limited thereto. Each of the organic material layer of the second light emitting layer LE2 of the second emission area EA2 and the organic material layer of the third light emitting layer LE3 of the third emission area EA3 may have the same configuration as the organic material layer of the first light emitting layer LE1 of the first emission area EA1 described above.

The organic material layer of the fourth light emitting layer LE4 of the fourth emission area EA4 emitting light of the second color (e.g., green) may include a phosphorescent material including a host material including CBP or mCP, and a dopant material including Ir(ppy)3(fac tris(2-phenylpyridine)iridium. Alternatively, the organic material layer of the fourth light emitting layer LE4 of the fourth emission area EA4 emitting the light of the second color may be a fluorescent material including tris(8-hydroxyquinolino)aluminum (Alq3), but the present disclosure is not limited thereto. Each of the organic material layer of the fifth light emitting layer LE5 of the fifth emission area EA5 and the organic material layer of the sixth light emitting layer LE6 of the sixth emission area EA6 may have the same configuration as the organic material layer of the fourth light emitting layer LE4 of the fourth emission area EA4 described above.

The organic material layer of the seventh light emitting layer LE7 of the seventh emission area EA7 emitting the light of the third color (e.g., blue) may include a phosphorescent material including a host material including CBP or mCP, and a dopant material. The dopant material may include (4,6-F2ppy) 2Irpic or L2BD111, but the present disclosure is not limited thereto. Each of the organic material layer of the eighth light emitting layer LE8 of the eighth emission area EA8 and the organic material layer of the ninth light emitting layer LE9 of the ninth emission area EA9 may have the same configuration as the organic material layer of the seventh light emitting layer LE7 of the seventh emission area EA7 described above.

The cathode electrode CA may be disposed on the first to ninth light emitting layers LE1 and LE9. The cathode electrode CA may be disposed to cover the first to ninth light emitting layers LE1 and LE9. The cathode electrode CA may be a common layer commonly disposed in the first to ninth light emitting layers LE1 and LE9. A capping layer may be further disposed on the cathode electrode CA. The capping layer may provide a barrier against oxygen and moisture. The capping layer could be made from inorganic materials, but is not limited thereto.

In the top emission structure, the cathode electrode CA may be formed of a transparent conductive material (TCO) such as ITO or IZO capable of transmitting light or a semi-transmissive conductive material such as magnesium (Mg), silver (Ag), or an alloy of magnesium (Mg) and silver (Ag). When the common electrode CM is formed of a semi-transmissive conductive material, the light emission efficiency can be increased due to a micro-cavity effect.

The encapsulation layer TEF may be formed on the light emitting element layer EMTL. The encapsulation layer TEF may include at least one inorganic layer to prevent oxygen or moisture from permeating into the light emitting element layer EMTL. In addition, the encapsulation layer TEF may include at least one organic layer to protect the light emitting element layer EMTL from foreign substances such as dust. For example, the encapsulation layer TEF may include a first encapsulation inorganic layer TEF1, an encapsulation organic layer TEF2, and a second encapsulation inorganic layer TEF3 sequentially stacked on the cathode electrode CA.

The first encapsulation inorganic layer TEF1 of the encapsulation layer TEF may be disposed on the cathode electrode CA, the second encapsulation organic layer TEF2 may be disposed on the first encapsulation inorganic layer TEF1, and the third encapsulation inorganic layer TEF3 may be disposed on the second encapsulation organic layer TEF2. The first encapsulation inorganic layer TEF1 and the third encapsulation inorganic layer TEF3 may be formed of multiple films in which one or more inorganic films of a silicon nitride layer, a silicon oxynitride layer, a silicon oxide layer, a titanium oxide layer and an aluminum oxide layer are alternately stacked. The second encapsulation organic layer TEF2 may be an organic film such as acryl resin, epoxy resin, phenolic resin, polyamide resin, polyimide resin or the like.

The first refractive layer LRL may be disposed on the encapsulation layer TEF. For example, the first refractive layer LRL may be disposed on the third encapsulation inorganic layer TEF3. In an embodiment, the first refractive layer LRL has at least one groove GR. The groove GR may have a concave shape recessed toward the substrate SUB from the top surface of the first refractive layer LRL. For example, the groove GR may have a concave shape in the reverse direction of a third direction DR3 (hereinafter, a third reverse direction). In the cross-sectional view as illustrated in FIG. 4, the groove GR of the first refractive layer LRL may have a width that gradually decreases along the direction toward the substrate SUB. For example, the groove GR may have the shape of an inverted triangle with a width that gradually decreases along the third reverse direction. For example, a portion of the first refractive layer LRL may be removed to form the groove GR.

The groove GR of the first refractive layer LRL may be disposed to overlap adjacent sub-pixels. For example, as in the example illustrated in FIG. 4, the groove GR may overlap sub-pixels (e.g., the first sub-pixel SPX1 and the second sub-pixel SPX2) that are disposed relatively closer (or have a relatively smaller size (or area)) among the sub-pixels of the first pixel PX1. For example, the groove GR may be positioned to overlap sub-pixels such as the first sub-pixel SPX1 and the second sub-pixel SPX2 of the first pixel PX1, which are located comparatively closer together or are smaller in size relative to other sub-pixels within the same pixel. As a specific example, the groove GR may overlap anode electrodes (e.g., the first anode electrode AN1 and the second anode electrode AN2) that are disposed relatively closer (or have a relatively smaller size (or area)) among the anode electrodes of the first pixel PX1.

According to an embodiment, as illustrated in FIG. 5, the groove GR may overlap sub-pixels (e.g., the fourth sub-pixel SPX4 and the fifth sub-pixel SPX5) that are disposed relatively closer (or have a relatively smaller size (or area)) among the sub-pixels of the second pixel PX2. As a specific example, the groove GR may overlap anode electrodes (e.g., the fourth anode electrode AN4 and the fifth anode electrode AN5) that are disposed relatively closer (or have a relatively smaller size (or area)) among the anode electrodes of the second pixel PX2.

According to an embodiment, as illustrated in FIG. 5, the groove GR may overlap sub-pixels (e.g., the seventh sub-pixel SPX7 and the eighth sub-pixel SPX8) that are disposed relatively closer (or have a relatively smaller size (or area)) among the sub-pixels of the third pixel PX3. As a specific example, the groove GR may overlap anode electrodes (e.g., the seventh anode electrode AN7 and the eighth anode electrode AN8) that are disposed relatively closer (or have a relatively smaller size (or area)) among the anode electrodes of the third pixel PX3.

In an embodiment, the center of the groove GR of the first refractive layer LRL (or the lowest portion of the groove GR) is disposed between adjacent sub-pixels. In an embodiment, the center does not overlap the adjacent sub-pixels. For example, the center may be located in a region that is between the adjacent sub-pixels. For example, the center of the groove GR may be disposed between sub-pixels that are disposed relatively closer (or have a relatively smaller size (or area)) among the sub-pixels of one pixel. For example, as illustrated in FIG. 4, the center of the groove GR may be disposed between the first sub-pixel SPX1 of the first pixel PX1 and the second sub-pixel SPX2 of the first pixel PX1. Additionally, as illustrated in FIG. 5, the center of the groove GR may be disposed between the fourth sub-pixel SPX4 of the second pixel PX2 and the fifth sub-pixel SPX5 of the second pixel PX2. Additionally, as illustrated in FIG. 5, the center of the groove GR may be disposed between the seventh sub-pixel SPX7 of the third pixel PX3 and the eighth sub-pixel SPX8 of the third pixel PX3.

According to an embodiment, as illustrated in FIG. 4, the center of the groove GR may be disposed between the first anode electrode AN1 of the first pixel PX1 and the second anode electrode AN2 of the first pixel PX1. Additionally, as illustrated in FIG. 5, the center of the groove GR may be disposed between the fourth anode electrode AN4 of the second pixel PX2 and the fifth anode electrode AN5 of the second pixel PX2. Additionally, as illustrated in FIG. 5, the center of the groove GR may be disposed between the seventh anode electrode AN7 of the third pixel PX3 and the eighth anode electrode AN8 of the third pixel PX3. In an embodiment, the center does not overlap the adjacent anode electrodes. For example, the center may be located in a region that is between the adjacent anode electrodes.

According to an embodiment, as illustrated in FIG. 4 or FIG. 5, the groove GR of the first refractive layer LRL may have a cross-section of an inverted triangle. For example, in cross-sectional view, the groove GR may have the shape of an inverted triangle with a width that gradually decreases along the direction from the first refractive layer LRL toward the substrate SUB.

According to an embodiment, the first refractive layer LRL may include an organic material. For example, the first refractive layer LRL may include a transparent organic layer.

In an embodiment, the first refractive layer LRL has a refractive index ranging from 1.4 to 1.5. For example, the first refractive layer LRL may have a refractive index of 1.5.

The light blocking layer BM may be disposed on the first refractive layer LRL. For example, as illustrated in FIG. 4, the light blocking layer BM may be disposed on the top surface of the first refractive layer LRL, close to the groove GR of the first refractive layer LRL. For example, the light blocking layer BM may be adjacent edges of the groove GR where a width of the groove GR is widest.

The second refractive layer HRL may be disposed on the light blocking layer BM and the first refractive layer LRL. The second refractive layer HRL may have a protrusion PRT. For example, the second refractive layer HRL may include a flat portion BS and the protrusion PRT, so that the protrusion PRT may have a shape that protrudes (or extends) from the bottom surface of the flat portion BS toward the substrate SUB. For example, the protrusion PRT may have a shape that protrudes in the third reverse direction. In cross-sectional view as illustrated in FIG. 4, the protrusion PRT of the second refractive layer HRL may have a width that gradually decreases along the direction toward the substrate SUB. For example, the protrusion PRT may have a width that gradually decreases along the third reverse direction. The protrusion PRT may have the same shape as the groove GR. For example, the protrusion PRT may have a cross-section of an inverted triangle. For example, the protrusion PRT may protrude into the groove GR to fill in the groove GR.

The protrusions PRT of the second refractive layer HRL may be disposed to overlap adjacent sub-pixels. For example, as in the example illustrated in FIG. 4, the protrusion PRT may overlap sub-pixels (e.g., the first sub-pixel SPX1 and the second sub-pixel SPX2) that are disposed relatively closer (or have a relatively smaller size (or area)) among the sub-pixels of the first pixel PX1. As a specific example, the protrusion PRT may overlap anode electrodes (e.g., the first anode electrode AN1 and the second anode electrode AN2) that are disposed relatively closer (or have a relatively smaller size (or area)) among the anode electrodes of the first pixel PX1.

According to an embodiment, as illustrated in FIG. 5, the protrusion PRT may overlap sub-pixels (e.g., the fourth sub-pixel SPX4 and the fifth sub-pixel SPX5) that are disposed relatively closer (or have a relatively smaller size (or area)) among the sub-pixels of the second pixel PX2. As a specific example, the protrusion PRT may overlap anode electrodes (e.g., the fourth anode electrode AN4 and the fifth anode electrode AN5) that are disposed relatively closer (or have a relatively smaller size (or area)) among the anode electrodes of the second pixel PX2.

According to an embodiment, as illustrated in FIG. 5, the protrusion PRT may overlap sub-pixels (e.g., the seventh sub-pixel SPX7 and the eighth sub-pixel SPX8) that are disposed relatively closer (or have a relatively smaller size (or area)) among the sub-pixels of the third pixel PX3. As a specific example, the protrusion PRT may overlap anode electrodes (e.g., the seventh anode electrode AN7 and the eighth anode electrode AN8) that are disposed relatively closer (or have a relatively smaller size (or area)) among the anode electrodes of the third pixel PX3.

In an embodiment, the center (or the corner portion of the protrusion PRT, or the end of the protrusion PRT) of the protrusion PRT of the first refractive layer LRL is disposed between adjacent sub-pixels. In an embodiment, the center does not overlap the adjacent sub-pixels, but is located in a region between the adjacent sub-pixels. For example, the center of the protrusion PRT may be disposed between sub-pixels that are disposed relatively closer (or have a relatively smaller size (or area)) among the sub-pixels of one pixel. For example, as illustrated in FIG. 4, the center of the protrusion PRT may be disposed between the first sub-pixel SPX1 of the first pixel PX1 and the second sub-pixel SPX2 of the first pixel PX1. Additionally, as illustrated in FIG. 5, the center of the protrusion PRT may be disposed between the fourth sub-pixel SPX4 of the second pixel PX2 and the fifth sub-pixel SPX5 of the second pixel PX2. Additionally, as illustrated in FIG. 5, the center of the protrusion PRT may be disposed between the seventh sub-pixel SPX7 of the third pixel PX3 and the eighth sub-pixel SPX8 of the third pixel PX3.

According to an embodiment, as illustrated in FIG. 4, the center of the protrusion PRT may be disposed between the first anode electrode AN1 of the first pixel PX1 and the second anode electrode AN2 of the first pixel PX1. Additionally, as illustrated in FIG. 5, the center of the protrusion PRT may be disposed between the fourth anode electrode AN4 of the second pixel PX2 and the fifth anode electrode AN5 of the second pixel PX2. Additionally, as illustrated in FIG. 5, the center of the protrusion PRT may be disposed between the seventh anode electrode AN7 of the third pixel PX3 and the eighth anode electrode AN8 of the third pixel PX3. In an embodiment, the center does not overlap the adjacent anode electrode, but is located in a region between the adjacent anode electrodes.

According to an embodiment, as illustrated in FIG. 4 or FIG. 5, the protrusion PRT of the first refractive layer LRL may have a cross-section of an inverted triangle. For example, in cross-sectional view, the protrusion PRT may have the shape of an inverted triangle with a width that gradually decreases along the direction from the second refractive layer HRL toward the substrate SUB.

According to an embodiment, the second refractive layer HRL may include an organic material. For example, the second refractive layer HRL may include a transparent organic layer.

In an embodiment, the refractive index of the second refractive layer HRL is different from the refractive index of the first refractive layer LRL. For example, the difference between the refractive index of the first refractive layer LRL and the refractive index of the second refractive layer HRL may be greater than or equal to 0.1. In an embodiment, the second refractive layer HRL has a higher refractive index than the first refractive layer LRL. For example, the second refractive layer HRL may have a refractive index ranging from 1.6 to 1.7. In an embodiment, the first refractive layer LRL has a refractive index of 1.5, and the second refractive layer HRL may has a refractive index of 1.7.

According to an embodiment, the protrusion PRT of the second refractive layer HRL may be inserted into the groove GR of the first refractive layer LRL. The protrusion PRT and the groove GR may have substantially the same shape. At this time, the protrusion PRT may face the inner wall of the groove GR. For example, between side surfaces S1 and S2 of the protrusion PRT, a first side surface S1 may face one inner wall of the groove GR, and a second side surface S2 may face the other inner wall of the groove GR. The first side surface S1 of the protrusion PRT may be in contact with one inner wall of the groove GR, and the second side surface S2 of the protrusion PRT may be in contact with the other inner wall of the groove GR.

Each of the first side surface S1 and the second side surface S2 of the protrusion PRT of the second refractive layer HRL may have a diagonal shape inclined or slanted at a certain angle. In other words, according to an embodiment, the first side surface S1 and the second side surface S2 of the protrusion PRT may have a symmetrical shape with respect to an imaginary straight line that is parallel to the thickness direction (e.g., the third direction DR3) of the second refractive layer HRL and passes through the center of the second refractive layer HRL. For example, the first side surface S1 and the second side surface S2 of the protrusion PRT may be designed symmetrically relative to a hypothetical straight line. This hypothetical line may run parallel to the thickness direction (identified as the third direction, DR3) of the second refractive layer HRL and intersect a center of the second refractive layer (HRL). Accordingly, the distance (or gap) between the first side surface S1 and the second side surface S2 of the protrusion PRT may be gradually reduced along the direction (e.g., in the reverse direction of the third direction DR3) toward the substrate SUB.

According to an embodiment, the first side surface S1 of the protrusion PRT may overlap one of two anode electrodes disposed adjacent to each other in one pixel, and the second side surface S2 of the protrusion PRT may overlap the other of the two anode electrodes. For example, as illustrated in FIG. 4, in the protrusion PRT disposed on the first anode electrode AN1 and the second anode electrode AN2, the first side surface S1 of the protrusion PRT overlaps the first anode electrode AN1, and the second side surface S2 of the protrusion PRT overlaps the second anode electrode AN2. Accordingly, the first anode electrode AN1 may overlap two refractive layers LRL and HRL having different refractive indices with respect to the first side surface S1, and the second anode electrode AN2 may overlap two refractive layers LRL and HRL having different refractive indices with respect to the second side surface S2.

When a connection portion between the flat portion BS and the protrusion PRT of the second refractive layer HRL is defined as a top surface S3 of the protrusion PRT, an angle θ between the top surface S3 and the first side surface S1 of the protrusion PRT may be an acute angle. For example, the angle θ between the top surface S3 of the protrusion PRT and the first side surface S1 of the protrusion PRT may range from 45 to 60 degrees. Meanwhile, the angle between the top surface S3 of the protrusion PRT and the second side surface S2 of the protrusion PRT may be equal to the angle θ between the top surface S3 and the first side surface S1 of the protrusion PRT.

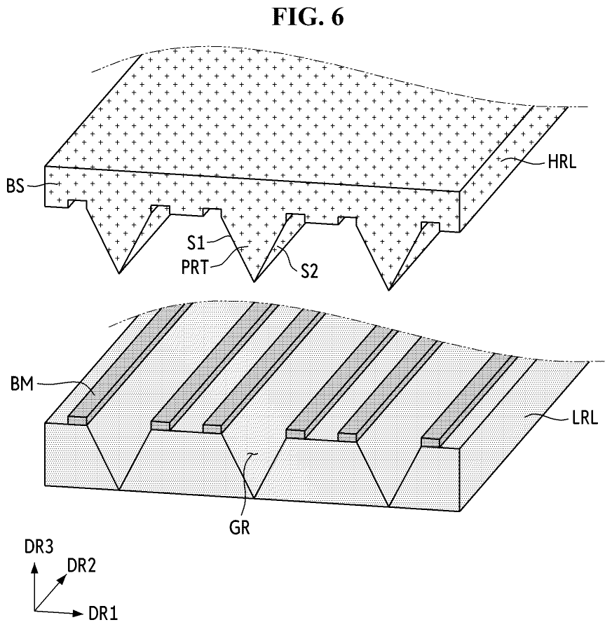

FIG. 6 is a perspective view of the first refractive layer LRL, the second refractive layer HRL, and the light blocking layer BM according to an embodiment. For example, the first refractive layer LRL, the second refractive layer HRL, and the light blocking layer BM of FIG. 6 may be perspective views of the first refractive layer LRL, the second refractive layer HRL, and the light blocking layer BM of FIG. 4 described above.

As illustrated in FIG. 6, the first refractive layer LRL may have a plurality of grooves GR. Each of the grooves GR may extend along the second direction DR2. The plurality of grooves GR may be disposed along the first direction DR1. Each of the grooves GR may have the shape of a triangular column or a prism shape.

As illustrated in FIG. 6, the second refractive layer HRL may have a plurality of protrusions PRT. Each of the plurality of protrusions PRT may be inserted into the plurality of grooves GR. Each of the protrusions PRT may extend along the second direction DR2. The plurality of protrusions PRT may be disposed along the first direction DR1. Each of the protrusions PRT may have the shape of a triangular column or a prism shape. The protrusions PRT may be configured to mate with the grooves GR.

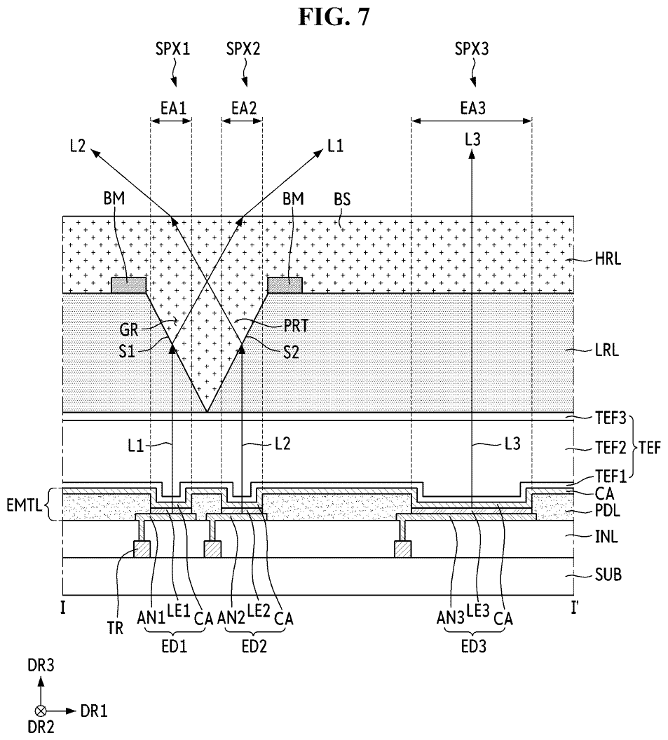

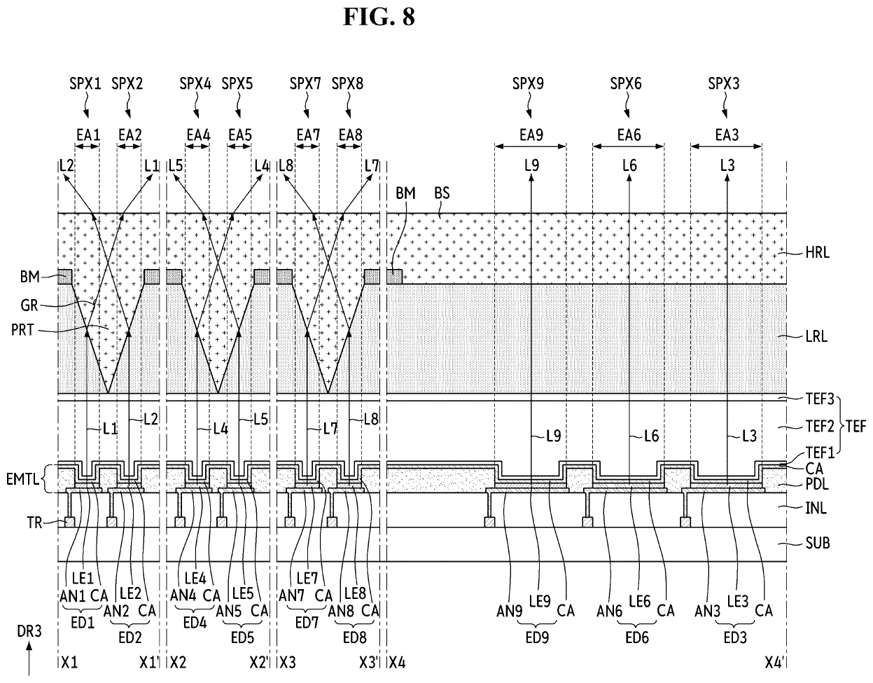

FIG. 7 and FIG. 8 illustrate the path of light in the display device 100 of FIG. 4 and FIG. 5.

As described above, since the first refractive layer LRL and the second refractive layer HRL have different refractive indices, and furthermore, the protrusion PRT of the first refractive layer LRL has a shape of an inverted triangular column (or an inverted prism), first light L1 emitted from the first sub-pixel SPX1 overlapping the first side surface S1 of the protrusion PRT and second light L2 emitted from the second sub-pixel SPX2 overlapping the second side surface S2 of the protrusion PRT may travel in different directions. In other words, lights from sub-pixels that overlap the protrusion PRT and are disposed adjacent to each other may cross each other and travel in different directions. For example, the first light L1 from the first emission area EA1 of the first sub-pixel SPX1 overlapping the first side surface S1 of the protrusion PRT may be refracted in the rightward direction, and the second light L2 from the second emission area EA2 of the second sub-pixel SPX2 overlapping the second side surface S2 of the protrusion PRT may be refracted in the leftward direction.

For example, as illustrated in FIG. 7, the first light L1 emitted from the first light emitting element ED1 of the first sub-pixel SPX1 may be refracted primarily in the right diagonal direction while passing through the interface between the first refractive layer LRL and the second refractive layer HRL at the first side surface S1 of the protrusion PRT, and then may be refracted secondarily in the right diagonal direction at a larger angle while passing through the interface between the second refractive layer HRL and the air layer. Accordingly, the first light L1 of the first sub-pixel SPX1 may travel in the rightward direction of the display device 100. Here, the refractive index of the air layer may be different from the refractive index of the second refractive layer HRL. For example, the refractive index of an air layer may be 1. The air layer may be disposed above or on the second refractive layer HRL. For example, the first light L1 emitted from the first light-emitting element ED1 of the first sub-pixel (SPX1) may undergo primary refraction in a right diagonal direction as it passes through the interface between the first refractive layer LRL and the second refractive layer HRL at the first side surface S1 of the protrusion PRT. Subsequently, it may undergo secondary refraction at a steeper angle in the right diagonal direction as it transitions through the interface between the second refractive layer (HRL) and the air layer.

Meanwhile, the second light L2 emitted from the second light emitting element ED2 of the second sub-pixel SPX2 may be refracted primarily in the left diagonal direction while passing through the interface between the first refractive layer LRL and the second refractive layer HRL at the second side surface S2 of the protrusion PRT, and then may be refracted secondarily in the left diagonal direction at a larger angle while passing through the interface between the second refractive layer HRL and the air layer. Accordingly, the second light L2 of the second sub-pixel SPX2 may travel in the leftward direction of the display device 100. For example, the second light L2 emitted from the second light-emitting element ED2 of the second sub-pixel SPX2 may undergo primary refraction in a left diagonal direction as it passes through the interface between the first refractive layer LRL and the second refractive layer HRL at the second side surface S2 of the protrusion (PRT). Subsequently, it may undergo secondary refraction at a steeper angle in the left diagonal direction as it transitions through the interface between the second refractive layer (HRL) and the air layer.

In the same manner, fourth light LA from the fourth emission area EA4 of the fourth sub-pixel SPX4 may be refracted in the rightward direction, fifth light L5 from the fifth emission area EA5 of the fifth sub-pixel SPX5 may be refracted in the leftward direction, seventh light L7 from the seventh emission area EA7 of the seventh sub-pixel SPX7 may be refracted in the rightward direction, and eighth light L8 from the eighth emission area EA8 of the eighth sub-pixel SPX8 may be refracted in the leftward direction.

Accordingly, an image implemented by lights (e.g., the lights L1, L4, and L7 of different colors) from the first sub-pixel SPX1, the fourth sub-pixel SPX4, and the seventh sub-pixel SPX7 may be provided in the rightward direction of the display device 100. In addition, an image implemented by lights (e.g., the lights L2, L5, and L8 of different colors) from the second sub-pixel SPX2, the fifth sub-pixel SPX5, and the eighth sub-pixel SPX8 may be provided in the leftward direction of the display device 100.

Meanwhile, third light L3 from the third emission area EA3 of the third sub-pixel SPX3 overlapping the flat portion BS of the second refractive layer HRL, sixth light L6 from the sixth emission area EA6 of the sixth sub-pixel SPX6 overlapping the flat portion BS of the second refractive layer HRL, and ninth light L9 from the ninth emission area EA9 of the ninth sub-pixel SPX9 overlapping the flat portion BS of the second refractive layer HRL may pass through the first refractive layer LRL, the second refractive layer HRL, and the air layer without being refracted.

For example, as illustrated in FIG. 7, the third light L3 emitted from the third light emitting element ED3 of the third sub-pixel SPX3 may pass through the interface between the first refractive layer LRL and the second refractive layer HRL in the flat portion BS without being refracted, and then pass through the interface between the second refractive layer HRL and the air layer without being refracted.

Accordingly, an image implemented by lights (e.g., the lights L3, L6, and L9 of different colors) from the third sub-pixel SPX3, the sixth sub-pixel SPX6, and the ninth sub-pixel SPX9 may be provided in the front direction of the display device 100.

In this way, according to the display device 100 of an embodiment, since the traveling paths of light provided from sub-pixels (e.g., SPX1, SPX2, and SPX3) within one pixel (e.g., PX1) are different, the viewing angle of the display device 100 may be adjustable.

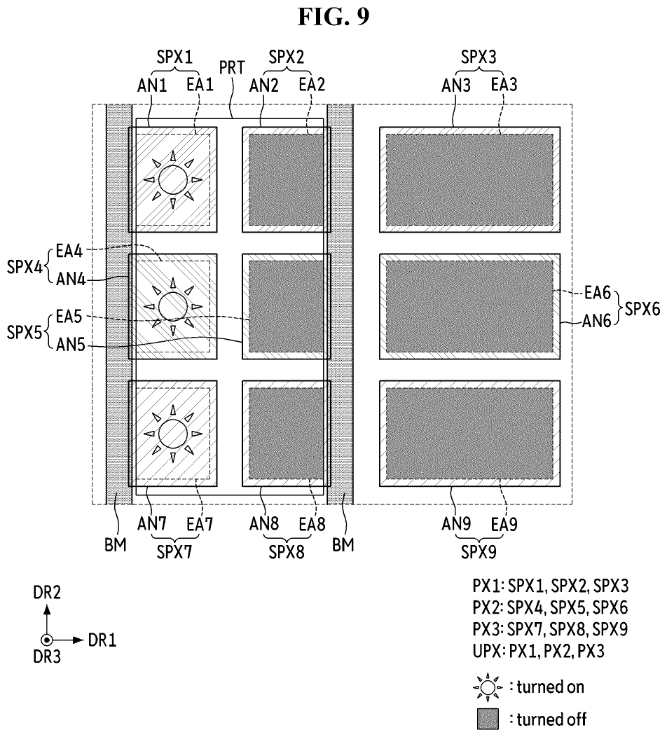

FIGS. 9, 10, and 11 explain the operation of the display device 100 according to an embodiment.

First, as described above, the first anode electrode AN1 of the first sub-pixel SPX1, the second anode electrode AN2 of the second sub-pixel SPX2, the fourth anode electrode AN4 of the fourth sub-pixel SPX4, the fifth anode electrode AN5 of the fifth sub-pixel SPX5, the seventh anode electrode AN7 of the seventh sub-pixel SPX7, and the eighth anode electrode AN8 of the eighth sub-pixel SPX8 may overlap the protrusion PRT of the second refractive layer HRL. In addition, the third anode electrode AN3 of the third sub-pixel SPX3, the sixth anode electrode AN6 of the sixth sub-pixel SPX6, and the ninth anode electrode AN9 of the ninth sub-pixel SPX9 may overlap the flat portion BS of the second refractive layer HRL.

The pixels of the display device 100 according to an embodiment may operate differently depending on a first display mode and a second display mode. For example, the first pixel PX1 may operate in the first display mode or operate in the second display mode.

Here, in the first display mode and the second display mode, the operations of the first pixel PX1, the second pixel PX2, and the third pixel PX3 are the same, so that the operation of the first pixel PX1 is representatively described as follows.

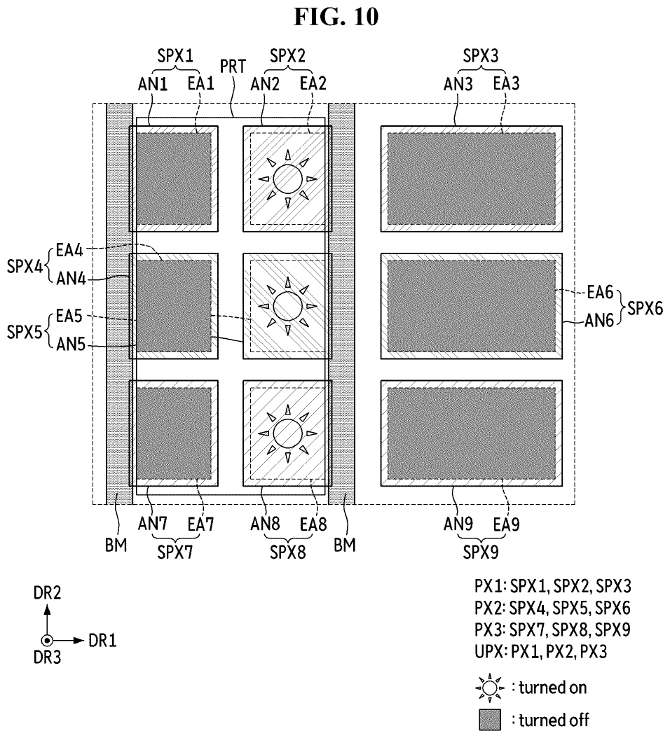

For example, when the first pixel PX1 operates in the first display mode, adjacent sub-pixels that overlap the protrusion PRT of the second refractive layer HRL among the sub-pixels of the first pixel PX1 may operate. For example, during a period (hereinafter, referred to as a first display mode period) in which the first pixel PX1 operates in the first display mode, as illustrated in FIGS. 9 and 10, the first sub-pixel SPX1 and the second sub-pixel SPX2 may alternately display images. Meanwhile, in the first display mode period, the third sub-pixel SPX3 of the first pixel PX1 does not provide an image. In other words, during the first display mode period, the first light emitting element ED1 of the first sub-pixel SPX1 and the second light emitting element ED2 of the second sub-pixel SPX2 may be alternately turned on (or illuminated), and the third light emitting element ED3 of the third sub-pixel SPX3 may be turned off. For example, during the first display mode period, the first light-emitting element ED1 and the second light-emitting element ED2 may alternate between being turned on (or illuminated), while the third light-emitting element ED3 remains turned off. As a specific example, the first display mode period may include a plurality of temporally consecutive sub-display periods, so that the first light emitting element ED1 may be turned on every odd-numbered sub-display period (see FIG. 9) and turned off every even-numbered sub-display period (see FIG. 10). On the other hand, the second light emitting element ED2 may be turned off every odd-numbered sub-display period (see FIG. 10) and turned on every even-numbered sub-display period (see FIG. 9). However, the present disclosure is not limited thereto, and the first light emitting element ED1 may be turned off every odd-numbered sub-display period and turned on every even-numbered sub-display period. On the other hand, the second light emitting element ED2 may be turned on every odd-numbered sub-display period and turned off every even-numbered sub-display period. Meanwhile, the third light emitting element ED3 may be maintained to be in a turned-off state during the first display mode period including the odd-numbered and even-numbered display periods (see FIGS. 9 and 10).

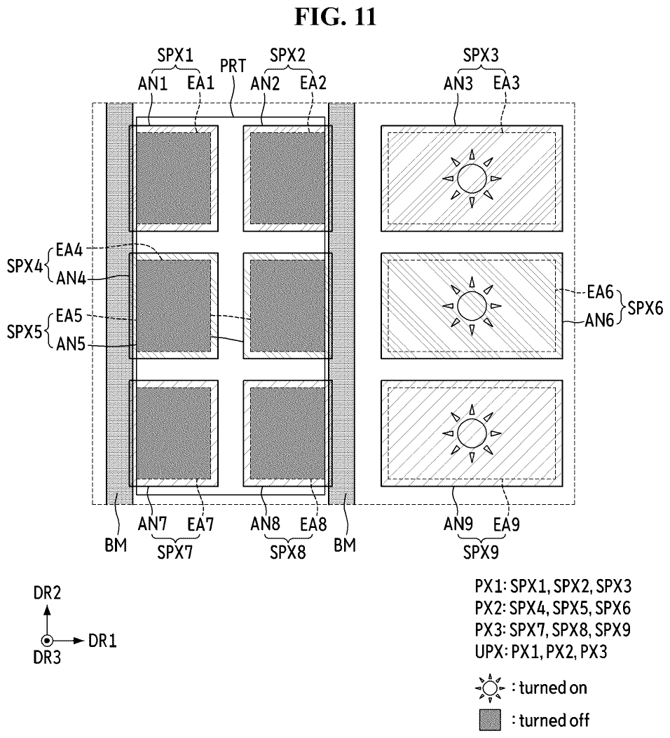

On the other hand, when the first pixel PX1 operates in the second display mode, a sub-pixel, which overlaps the flat portion BS of the second refractive layer HRL, among the sub-pixels of the first pixel PX1 may operate. For example, during a period (hereinafter, referred to as a second display mode period) in which the first pixel PX1 operates in the second display mode, as illustrated in FIG. 11, the third sub-pixel SPX3 may display an image. Meanwhile, in the second display mode period, the first sub-pixel SPX1 and the second sub-pixel SPX2 do not provide an image. In other words, during the second display mode period, the third light emitting element ED3 of the third sub-pixel SPX3 may be turned on, and each of the first light emitting element ED1 of the first sub-pixel SPX1 and the second light emitting element ED2 of the second sub-pixel SPX2 may be turned off. In an embodiment, the emission driver EMD controls the turning on and off of the light emitting elements during the display periods.

When the first light emitting element ED1 of the first sub-pixel SPX1 is turned on, the first light L1 from the first light emitting element ED1 may be refracted in the rightward direction of the display device 100 and provided in the rightward direction of the display device 100. Accordingly, the first light L1 from the first light emitting element ED1 may be provided in the rightward direction of the display device 100 every odd-numbered sub-display period of the first display mode period.

When the second light emitting element ED2 of the second sub-pixel SPX2 is turned on, the second light L2 from the second light emitting element ED2 may be refracted in the leftward direction of the display device 100 and provided in the leftward direction of the display device 100. Accordingly, the second light L2 from the second light emitting element ED2 may be provided in the leftward direction of the display device 100 every even-numbered sub-display period of the first display mode period.

When the third light emitting element ED3 of the third sub-pixel SPX3 is turned on, the third light L3 from the third light emitting element ED3 may be provided in the front direction of the display device 100 without being refracted. Accordingly, during the second display mode period, the third light L3 from the third light emitting element ED3 may be provided in the front direction of the display device 100. For example, the third light L3 may travel directly in the forward direction of the display device 100 without undergoing refraction. Consequently, during the second display mode period, the third light L3 may be emitted directly toward the front of the display device 100.

In the same manner, during the first display mode period, the fourth light emitting element ED4 of the fourth sub-pixel SPX4 and the fifth light emitting element ED5 of the fifth sub-pixel SPX5 may be alternately turned on (or illuminated), and the sixth light emitting element ED6 of the sixth sub-pixel SPX6 may be turned off. In addition, during the second display mode period, the sixth light emitting element ED6 of the sixth sub-pixel SPX6 may be turned on, and each of the fourth light emitting element ED4 of the fourth sub-pixel SPX4 and the fifth light emitting element ED5 of the fifth sub-pixel SPX5 may be turned off. At this time, the fourth light L4 from the fourth light emitting element ED4 may be refracted and travel in the rightward direction of the display device 100, the fifth light L5 from the fifth light emitting element ED5 may be refracted and travel in the leftward direction of the display device 100, and the sixth light L6 from the sixth light emitting element ED6 may travel in the front direction of the display device 100 without being refracted. For example, the fourth light L4 may be refracted and directed toward the right side of the display device 100. Similarly, the fifth light L5 may be refracted and directed toward the left side of the display device 100, while the sixth light L6 from may travel straight in the forward direction of the display device 100 without undergoing refraction.

In the same manner, during the first display mode period, the seventh light emitting element ED7 of the seventh sub-pixel SPX7 and the eighth light emitting element ED8 of the eighth sub-pixel SPX8 may be alternately turned on (or illuminated), and the ninth light emitting element ED9 of the ninth sub-pixel SPX9 may be turned off. In addition, during the second display mode period, the ninth light emitting element ED9 of the ninth sub-pixel SPX9 may be turned on, and each of the seventh light emitting element ED7 of the seventh sub-pixel SPX7 and the eighth light emitting element ED8 of the eighth sub-pixel SPX8 may be turned off. At this time, the seventh light L7 from the seventh light emitting element ED7 may be refracted and travel in the rightward direction of the display device 100, the eighth light L8 from the eighth light emitting element ED8 may be refracted and travel in the leftward direction of the display device 100, and the ninth light L9 from the ninth light emitting element ED9 may travel in the front direction of the display device 100 without being refracted. For example, the seventh light L7 may be refracted and directed toward the right side of the display device 100. Similarly, the eighth light L8 may be refracted and directed toward the left side of the display device 100, while the ninth light L9 may travel straight in the forward direction of the display device 100 without undergoing refraction.

In this way, during the first display mode period, the display device 100 may provide images alternately in the rightward direction and the leftward direction. In addition, during the second display mode period, the display device 100 may continuously provide images in the front direction.

Accordingly, in the first display mode period, a user positioned on the right side of the display device 100 and a user positioned on the left side of the display device 100 may watch different images (or watch the images almost simultaneously), and in the second display mode period, a user positioned on the right side of the display device 100 and a user positioned on the left side of the display device 100 may watch the same image simultaneously.

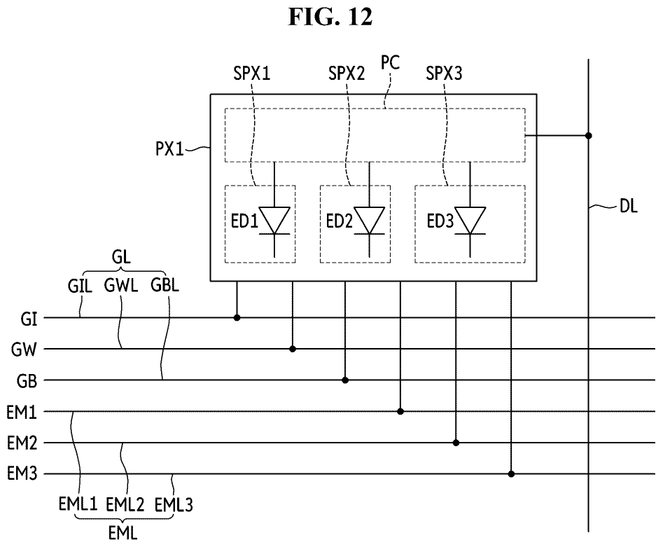

FIG. 12 explains how the first pixel PX1 is connected to the gate line and the data line of the display device 100 according to an embodiment.

The first pixel PX1 may include a pixel circuit PC, the first light emitting element ED1, the second light emitting element ED2, and the third light emitting element ED3.

The first light emitting element ED1, the second light emitting element ED2, and the third light emitting element ED3 may be connected to the pixel circuit PC.

A gate line GL may include, for example, an initialization gate line GIL, a write gate line GWL, and a bias gate line GBL. The initialization gate line GIL, the write gate line GWL, and the bias gate line GBL may be connected to the pixel circuit PC.

An initialization gate signal GI may be applied to the initialization gate line GIL, a write gate signal GW may be applied to the write gate line GWL, and a bias gate signal GB may be applied to the bias gate line GBL. The initialization gate signal GI, the write gate signal GW, and the bias gate signal GB described above may be provided from the gate driver GAD described above.

An emission control line EML may include, for example, a first emission control line EML1, a second emission control line EML2, and a third emission control line EML3. The first emission control line EML1, the second emission control line EML2, and the third emission control line EML3 may be connected to the pixel circuit PC.

A first emission control signal EM1 may be applied to the first emission control line EML1, a second emission control signal EM2 may be applied to the second emission control line EML2, and a third emission control signal EM3 may be applied to the third emission control line EML3. The first emission control signal EM1, the second emission control signal EM2, and the third emission control signal EM3 described above may be provided from the emission driver EMD described above.

A data line DL may be connected to the pixel circuit PC. A first data voltage, a second data voltage, and a third data voltage including different image information may be applied to the data line DL. The first data voltage, the second data voltage, and the third data voltage may be provided from the data driver DAD.

The first pixel PX1 may be connected to the initialization gate line GIL, the write gate line GWL, the bias gate line GBL, the first emission control line EML1, the second emission control line EML2, the third emission control line EML3, and the data line DL.

According to an embodiment, the first data voltage and the second data voltage may be alternately applied to the data line DL in the first display mode period described above. For example, the first data voltage may be supplied to the first sub-pixel SPX1 of the first pixel PX1 every odd-numbered sub-display period, and the second data voltage may be supplied to the second sub-pixel SPX2 of the first pixel PX1 every even-numbered sub-display period. Accordingly, different images may be provided in different directions in the first sub-display period and the second sub-display period. For example, in the first sub-display period, the first sub-pixel SPX1 may generate an image according to the first data voltage and provide the image in the rightward direction of the display device 100, and in the second sub-display period, the second sub-pixel SPX2 may generate an image according to the second data voltage and provide the image in the leftward direction of the display device 100. For instance, during the first sub-display period, the first sub-pixel SPX1 may generate an image based on the first data voltage and project it toward the right side of the display device 100. Similarly, during the second sub-display period, the second sub-pixel SPX2 may generate an image based on the second data voltage and project it toward the left side of the display device 100. According to an embodiment, in the first display mode period, the first data voltage and the second data voltage from the data driver DAD may be alternately applied to the data line DL in a time-division manner.

In the second display mode period described above, the third data voltage may be applied to the data line DL. For example, the third data voltage may be supplied to the third sub-pixel SPX3 of the first pixel PX1. Accordingly, in the second display mode period, the image may be provided in the front direction of the display device 100. For example, in the second display mode period, the third sub-pixel SPX3 may generate an image according to the third data voltage and provide the image in the front direction of the display device 100.

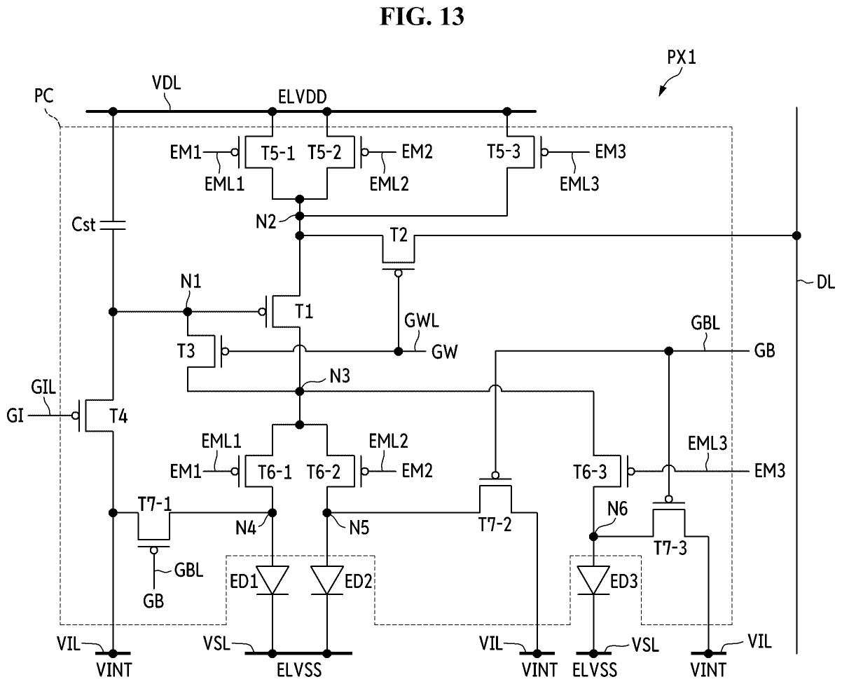

FIG. 13 is a diagram showing an equivalent circuit of the first pixel PX1 of FIG. 12.

The first pixel PX1 may include the pixel circuit PC and a plurality of light emitting elements ED1, ED2, and ED3 connected to the pixel circuit PC.

As illustrated in FIG. 13, the pixel circuit PC of the first pixel PX1 may include a first transistor T1, a second transistor T2, a third transistor T3, a fourth transistor T4, a fifth-first transistor T5-1, a fifth-second transistor T5-2, a fifth-third transistor T5-3, a sixth-first transistor T6-1, a sixth-second transistor T6-2, a sixth-third transistor T6-3, a seventh-first transistor T7-1, a seventh-second transistor T7-2, a seventh-third transistor T7-3, and a capacitor Cst.

The first transistor T1 may include a gate electrode connected to a first node N1, a source electrode connected to a second node N2, and a drain electrode connected to a third node N3. The first transistor T1 may adjust a driving current according to the data voltage applied to the first node N1 and may selectively supply the adjusted driving current to any one of the first to third light emitting elements ED1 and ED3.

The second transistor T2 may include a gate electrode connected to the write gate line GWL, a source electrode connected to the data line DL, and a drain electrode connected to the second node N2.

The third transistor T3 may include a gate electrode connected to the write gate line GWL, a source electrode connected to the third node N3, and a drain electrode connected to the first node N1.

The fourth transistor T4 may include a gate electrode connected to the initialization gate line GIL, a source electrode connected to the first node N1, and a drain electrode connected to the initialization voltage line VIL. The initialization voltage line VIL may be supplied with an initialization voltage VINT.

The fifth-first transistor T5-1 may include a gate electrode connected to the first emission control line EML1, a source electrode connected to a driving voltage line VDL, and a drain electrode connected to the second node N2. A driving voltage ELVDD may be applied to the driving voltage line VDL.

The fifth-second transistor T5-2 may include a gate electrode connected to the second emission control line EML2, a source electrode connected to the driving voltage line VDL, and a drain electrode connected to the second node N2.

The fifth-third transistor T5-3 may include a gate electrode connected to the third emission control line EML3, a source electrode connected to the driving voltage line VDL, and a drain electrode connected to the second node N2.

The sixth-first transistor T6-1 may include a gate electrode connected to the first emission control line EML1, a source electrode connected to the third node N3, and a drain electrode connected to a fourth node N4.

The sixth-second transistor T6-2 may include a gate electrode connected to the second emission control line EML2, a source electrode connected to the third node N3, and a drain electrode connected to a fifth node N5.

The sixth-third transistor T6-3 may include a gate electrode connected to the third emission control line EML3, a source electrode connected to the third node N3, and a drain electrode connected to a sixth node N6.

The seventh-first transistor T7-1 may include a gate electrode connected to the bias gate line GBL, a source electrode connected to the fourth node N4, and a drain electrode connected to the initialization voltage line VIL.

The seventh-second transistor T7-2 may include a gate electrode connected to the bias gate line GBL, a source electrode connected to the fifth node N5, and a drain electrode connected to the initialization voltage line VIL.

The seventh-third transistor T7-3 may include a gate electrode connected to the bias gate line GBL, a source electrode connected to the sixth node N6, and a drain electrode connected to the initialization voltage line VIL.

The capacitor Cst may be connected between the driving voltage line VDL and the first node N1. For example, a first capacitor electrode of the capacitor Cst may be connected to the driving voltage line VDL, and a second capacitor electrode of the capacitor Cst may be connected to the first node N1.

The first light emitting element ED1 may include the first anode electrode AN1 connected to the fourth node N4 and the cathode electrode CA connected to the common voltage line VSL. A common voltage ELVSS may be applied to the common voltage line VSL.

The second light emitting element ED2 may include the second anode electrode AN2 connected to the fifth node N5 and the cathode electrode CA connected to the common voltage line VSL.

The third light emitting element ED3 may include the third anode electrode AN3 connected to the sixth node N6 and the cathode electrode CA connected to the common voltage line VSL.

In an embodiment, the driving voltage ELVDD is greater than the common voltage ELVSS and the initialization voltage VINT.

As illustrated in FIG. 13, each of the first transistor T1, the second transistor T2, the third transistor T3, the fourth transistor T4, the fifth-first transistor T5-1, the fifth-second transistor T5-2, the fifth-third transistor T5-3, the sixth-first transistor T6-1, the sixth-second transistor T6-2, the sixth-third transistor T6-3, the seventh-first transistor T7-1, the seventh-second transistor T7-2, and the seventh-third transistor T7-3 may be a P-type transistor. However, the present disclosure is not limited thereto, and at least one of the first transistor T1, the second transistor T2, the third transistor T3, the fourth transistor T4, the fifth-first transistor T5-1, the fifth-second transistor T5-2, the fifth-third transistor T5-3, the sixth-first transistor T6-1, the sixth-second transistor T6-2, the sixth-third transistor T6-3, the seventh-first transistor T7-1, the seventh-second transistor T7-2, or the seventh-third transistor T7-3 may be an N-type transistor.

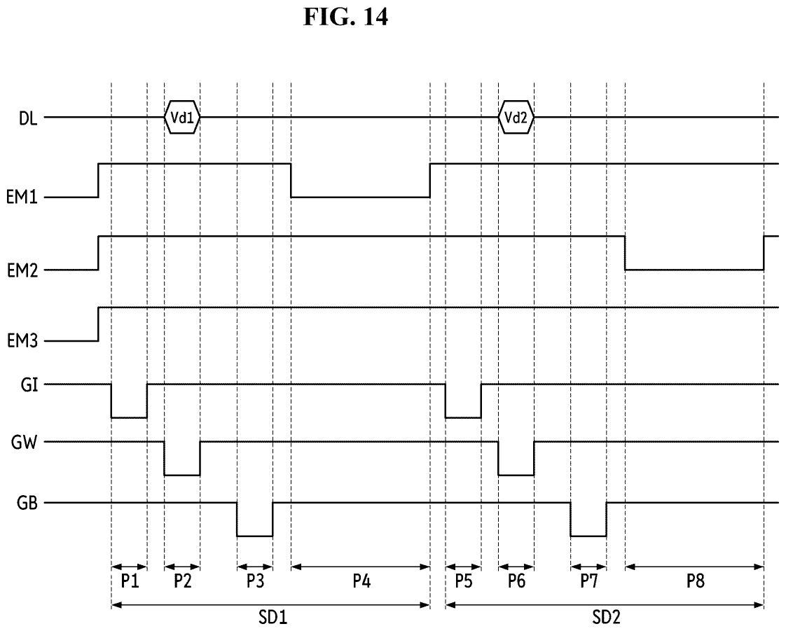

FIG. 14 is a timing diagram of gate signals, emission control signals, and data voltages in the first display mode period.

When the display device 100 or the first pixel PX1 of the display device 100 is driven in the first display mode, the first display mode period may include a first sub-display period SD1 and a second sub-display period SD2. At this time, each sub-display period may include initialization periods P1 and P5, data write periods P2 and P6, reset periods P3 and P7, and emission periods P4 and P8. For example, the first sub-display period SD1 may include the initialization period P1, the data write period P2, the reset period P3, and the emission period P4. In addition, the second sub-display period SD2 may include the initialization period P5, the data write period P6, the reset period P7, and the emission period P8.

Each of the initialization gate signal GI, the write gate signal GW, the bias gate signal GB, the first emission control signal EM1, the second emission control signal EM2, and the third emission control signal EM3 may have an active level or a non-active level for each of the periods P1 to P4 and P5 to P8. Here, the active level of each of the signals GI, GW, GB, and EM1 to EM3 described above may mean a voltage at a level capable of turning on a corresponding transistor to which the corresponding signal is applied. In other words, the active level signal may have a value greater than the threshold voltage of the corresponding transistor. For example, as illustrated in FIG. 13, when each of the transistors T1 to T7-3 is a P-type transistor, the active level of each of the signals GI, GW, GB, and EM1 to EM3 may mean a low level (e.g., a negative level or a low voltage level).

Meanwhile, the non-active level of each of the signals GI, GW, GB, and EM1 to EM3 may mean a voltage at a level capable of turning off a corresponding transistor. In other words, the non-active level signal may have a smaller value than the threshold voltage of the corresponding transistor. For example, as illustrated in FIG. 13, when each of the transistors T1 to T7-3 is a P-type transistor, the non-active level of each of the signals GI, GW, GB, and EM1 to EM3 may mean a high level (e.g., a positive level or a high voltage level).

In contrast, when each of the transistors T1 to T7-3 is of the N type, the active level of each signal may mean a high level (e.g., a positive level or a high voltage level), and the non-active level of each signal may mean a low level (e.g., a negative level or a low voltage level).

In the initialization period P1 of the first sub-display period SD1, the initialization gate signal GI has the active level. Meanwhile, in the initialization period P1 of the first sub-display period SD1, each of the first emission control signal EM1, the second emission control signal EM2, the third emission control signal EM3, the write gate signal GW, and the bias gate signal GB has the non-active level.

In the data write period P2 of the first sub-display period SD1, the write gate signal GW has the active level. Meanwhile, in the data write period P2 of the first sub-display period SD1, each of the first emission control signal EM1, the second emission control signal EM2, the third emission control signal EM3, the initialization gate signal GI, and the bias gate signal GB have the non-active level. Additionally, in the data write period P2 of the first sub-display period SD1, a first data voltage Vd1 may be applied to the data line DL.

In the reset period P3 of the first sub-display period SD1, the bias gate signal GB has the active level. Meanwhile, in the reset period P3 of the first sub-display period SD1, each of the first emission control signal EM1, the second emission control signal EM2, the third emission control signal EM3, the write gate signal GW, and the write gate signal GW have the non-active level.

In the emission period P4 of the first sub-display period SD1, the first emission control signal EM1 have the active level. Meanwhile, in the emission period P4 of the first sub-display period SD1, each of the second emission control signal EM2, the third emission control signal EM3, the initialization gate signal GI, the write gate signal GW, and the bias gate signal GB have the non-active level.

Meanwhile, the timings of the signals GI, GW, GB, and EM1 to EM3 described above in the initialization period P5, the data write period P6, the reset period P7, and the emission period P8 of the second sub-display period SD2 are identical to the timings of the signals GI, GW, GB, and EM1 to EM3 in the initialization period P1, the data write period P2, the reset period P3, and the emission period P4 of the first sub-display period SD1 described above, respectively. However, a second data voltage Vd2 may be applied to the data line DL in the data write period P6 of the second sub-display period SD2.

The operation of the first pixel PX1 is described as follows based on the first pixel PX1 of FIG. 13 and the signals in the first sub-display period SD1 of FIG. 14.

First, the operation of the first pixel PX1 in the initialization period P1 of the first sub-display period SD1 is described as follows.

In the initialization period P1 of the first sub-display period SD1, the initialization gate signal GI of the active level may be applied to the gate electrode of the fourth transistor T4 through the initialization gate line GIL. Accordingly, the fourth transistor T4 may be turned on. Then, the initialization voltage VINT from the initialization voltage line VIL may be applied to the first node N1 through the turned-on fourth transistor T4. Accordingly, the voltage of the first node N1 may be initialized.

Subsequently, the operation of the first pixel PX1 in the data write period P2 of the first sub-display period SD1 is described as follows.

In the data write period P2 of the first sub-display period SD1, the write gate signal GW of the active level may be applied to the gate electrode of the second transistor T2 and the gate electrode of the third transistor T3 through the write gate line GWL, respectively. Accordingly, each of the second transistor T2 and the third transistor T3 may be turned on. Then, the first data voltage Vd1 from the data line DL may be applied to the second node N2 through the turned-on second transistor T2, and the first node N1 and the third node N3 may be connected to each other through the turned-on third transistor T3. When the first node N1 and the third node N3 are electrically connected to each other, the gate electrode and the drain electrode of the first transistor T1 may be electrically connected to each other. Accordingly, the first transistor T1 may be driven in a diode manner, so that charges from the second node N2 may be introduced into the third node N3 through the first transistor T1 turned on in a diode manner. Then, the voltage of the second node N2 gradually decreases, and accordingly, the voltage difference (hereinafter, gate-source voltage) between the gate electrode and the source electrode of the first transistor T1 may gradually decrease. When the gate-source voltage of the first transistor T1 gradually decreases and the gate-source voltage reaches the threshold voltage of the first transistor T1, the first transistor T1 may be turned off. Accordingly, the threshold voltage of the first transistor T1 may be detected at the time when the first transistor T1 is turned off, and the detected threshold voltage of the first transistor T1 may be stored and maintained by the capacitor Cst at the first node N1. Accordingly, the voltage of the first node N1 may include the first data voltage Vd1, which is compensated for the threshold voltage of the first transistor T1.

Next, the operation of the first pixel PX1 in the reset period P3 of the first sub-display period SD1 is described as follows.

In the reset period P3 of the first sub-display period SD1, the bias gate signal GB of the active level may be applied to the gate electrode of the seventh-first transistor T7-1, the gate electrode of the seventh-second transistor T7-2, and the gate electrode of the seventh-third transistor T7-3 through the bias gate line GBL, respectively. Accordingly, each of the seventh-first transistor T7-1, the seventh-second transistor T7-2, and the seventh-third transistor T7-3 may be turned on. Then, the initialization voltage VINT from the initialization voltage line VIL may be applied to the fourth node N4 through the turned-on seventh-first transistor T7-1, the initialization voltage VINT from the initialization voltage line VIL may be applied to the fifth node N5 through the turned-on seventh-second transistor T7-2, and the initialization voltage VINT from the initialization voltage line VIL may be applied to the sixth node N6 through the turned-on seventh-third transistor T7-3. Accordingly, the voltage of each of the fourth node N4, the fifth node N5, and the sixth node N6 may be reset. In other words, the voltage of each of the first anode electrode AN1 of the first light emitting element ED1 connected to the fourth node N4, the second anode electrode AN2 of the second light emitting element ED2 connected to the fifth node N5, and the third anode electrode AN3 of the third light emitting element ED3 connected to the sixth node N6 may be initialized. Accordingly, the display device 100 may exhibit enhanced expressiveness in the black grayscale levels.

Subsequently, the operation of the first pixel PX1 in the emission period P4 of the first sub-display period SD1 is described as follows.

In the emission period P4 of the first sub-display period SD1, the first emission control signal EM1 of the active level may be applied to the gate electrode of the fifth-first transistor T5-1 and the gate electrode of the sixth-first transistor T6-1 through the first emission control line EML1, respectively. Accordingly, the fifth-first transistor T5-1 and the sixth-first transistor T6-1 may each be turned on. Then, a current path may be generated between the first transistor T1 and the first light emitting element ED1 through the turned-on fifth-first transistor T5-1 and the turned-on sixth-first transistor T6-1. Accordingly, the driving current controlled by the first transistor T1 may be supplied to the first light emitting element ED1. In other words, the operation of the first transistor T1 may be controlled by the first data voltage Vd1, which is compensated for the threshold voltage of the first transistor T1, and the driving current may be supplied to the first light emitting element ED1 through the controlled first transistor T1. Accordingly, the first light emitting element ED1 may be illuminated (or turned on) in the emission period P4 of the first sub-display period SD1.

Thereafter, the initialization period P5, the data write period P6, the reset period P7, and the emission period P8 of the second sub-display period SD2 may be sequentially performed. The operations of the initialization period P5, the data write period P6, the reset period P7, and the emission period P8 in the second sub-display period SD2 have differences from the operations of the initialization period P1, the data write period P2, the reset period P3, and the emission period P4 in the first sub-display period SD1 described above in the timing diagram of the emission control signals, so that the differences will be mainly described as follows.

For example, in the emission period P8 of the second sub-display period SD2, the second emission control signal EM2 of the active level may be applied to the gate electrode of the fifth-second transistor T5-2 and the gate electrode of the sixth-second transistor T6-2 through the second emission control line EML2, respectively. Accordingly, each of the fifth-second transistor T5-2 and the sixth-second transistor T6-2 may be turned on. Then, a current path may be generated between the first transistor T1 and the second light emitting element ED2 through the turned-on fifth-second transistor T5-2 and the turned-on sixth-second transistor T6-2. Accordingly, the driving current controlled by the first transistor T1 may be supplied to the second light emitting element ED2. In other words, the operation of the first transistor T1 may be controlled by the second data voltage Vd2, which is compensated for the threshold voltage of the first transistor T1, and the driving current may be supplied to the second light emitting element ED2 through the controlled first transistor T1. Accordingly, the second light emitting element ED2 may be illuminated (or turned on) in the emission period P4 of the second sub-display period SD2.

In this way, by alternately performing the first sub-display period SD1 and the second sub-display period SD2 during the first display mode period, the first pixel PX1 (or display device 100) may alternately provide the first light L1 from the first light emitting element ED1 and the second light L2 from the second light emitting element ED2 during the first display mode period. At this time, the first light L1 from the first light emitting element ED1 may be provided in the rightward direction of the display device 100, and the second light L2 from the second light emitting element ED2 may be provided in the leftward direction of the display device 100.

In the first display mode period, each of the second pixel PX2 and the third pixel PX3 may also be driven in the same manner as the first pixel PX1 illustrated in FIGS. 13 and 14 described above.

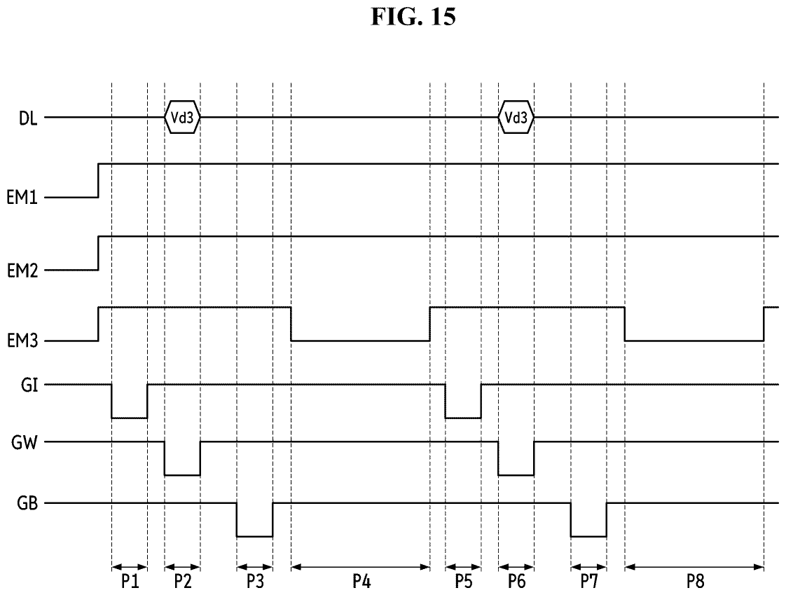

FIG. 15 is a timing diagram of gate signals, emission control signals, and data voltages in the second display mode period.

When the display device 100 or the first pixel PX1 of the display device 100 is driven in the second display mode, the second display mode period may include the initialization period P1, P5, the data write period P2, P6, the reset period P3, P7, and the emission period P4, P8.

In the initialization period P1 of the second display mode period, the initialization gate signal GI has the active level. Meanwhile, in the initialization period P1 of the second display mode period, each of the first emission control signal EM1, the second emission control signal EM2, the third emission control signal EM3, the write gate signal GW, and the bias gate signal GB has the non-active level.

In the data write period P2 of the second display mode period, the write gate signal GW has the active level. Meanwhile, in the data write period P2 of the second display mode period, each of the first emission control signal EM1, the second emission control signal EM2, the third emission control signal EM3, the initialization gate signal GI, and the bias gate signal GB have the non-active level. Additionally, in the data write period P2 of the second display mode period, the third data voltage may be applied to the data line.

In the reset period P3 of the second display mode period, the bias gate signal GB has the active level. Meanwhile, in the reset period P3 of the first sub-display period SD1, each of the first emission control signal EM1, the second emission control signal EM2, the third emission control signal EM3, the write gate signal GW, and the write gate signal GW has the non-active level.

In the emission period P4 of the second display mode period, the third emission control signal EM3 has the active level. Meanwhile, in the emission period P4 of the second display mode period, each of the first emission control signal EM1, the second emission control signal EM2, the initialization gate signal GI, the write gate signal GW, and the bias gate signal GB have the non-active level.

The operation of the first pixel PX1 is described as follows based on the first pixel PX1 of FIG. 13 and the signals in the second display mode period of FIG. 15.

The operation of the first pixel PX1 in the second display mode period based on FIGS. 13 and 15 is different from the operation of the first pixel PX1 in the first sub-display period SD1 based on FIGS. 13 and 14 described above in the operation in the emission period P4, so that the difference will be mainly described as follows.

In the emission period P4 of the second display mode period, the third emission control signal EM3 of the active level may be applied to the gate electrode of the fifth-third transistor T5-3 and the gate electrode of the sixth-third transistor T6-3 through the third emission control line EML3, respectively. Accordingly, each of the fifth-third transistor T5-3 and the sixth-third transistor T6-3 may be turned on. Then, a current path may be generated between the first transistor T1 and the third light emitting element ED3 through the turned-on fifth-third transistor T5-3 and the turned-on sixth-third transistor T6-3. Accordingly, the driving current controlled by the first transistor T1 may be supplied to the third light emitting element ED3. In other words, the operation of the first transistor T1 may be controlled by a third data voltage Vd3, which is compensated for the threshold voltage of the first transistor T1, and the driving current may be supplied to the third light emitting element ED3 through the controlled first transistor T1. Accordingly, the third light emitting element ED3 may be illuminated (or turned on) in the emission period P4 of the second display mode period.

In this way, during the second display mode period, the first pixel PX1 (or display device 100) may continuously provide the third light L3 from the third light emitting element ED3. At this time, the third light L3 from the third light emitting element ED3 may be provided in the front direction of the display device 100.

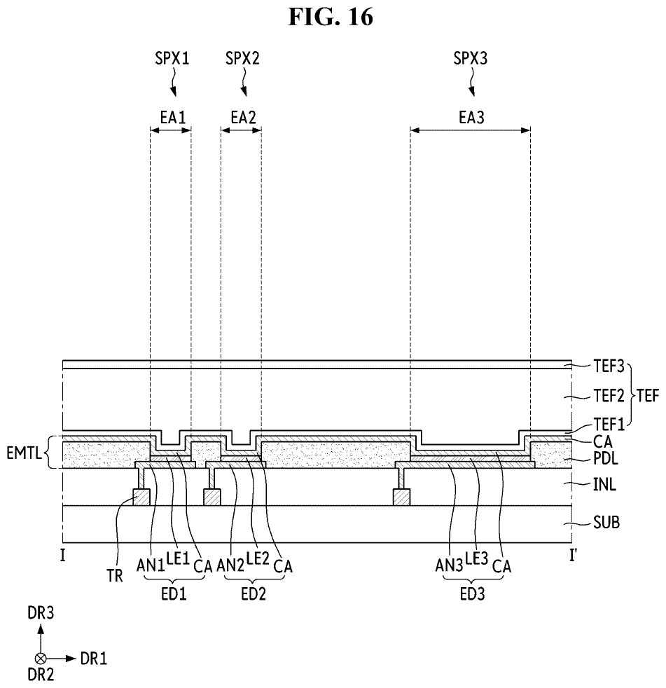

FIGS. 16 to 25 are process cross-sectional views illustrating a method of manufacturing the display device 100 according to an embodiment.

As illustrated in FIG. 16, a substrate SUB is formed, transistors TR are formed on the substrate SUB, an insulating layer INL is formed on the transistors TR and the substrate SUB, a light emitting layer EMTL is formed on the insulating layer INL and an encapsulation layer TEF is formed on the light emitting layer EMTL.

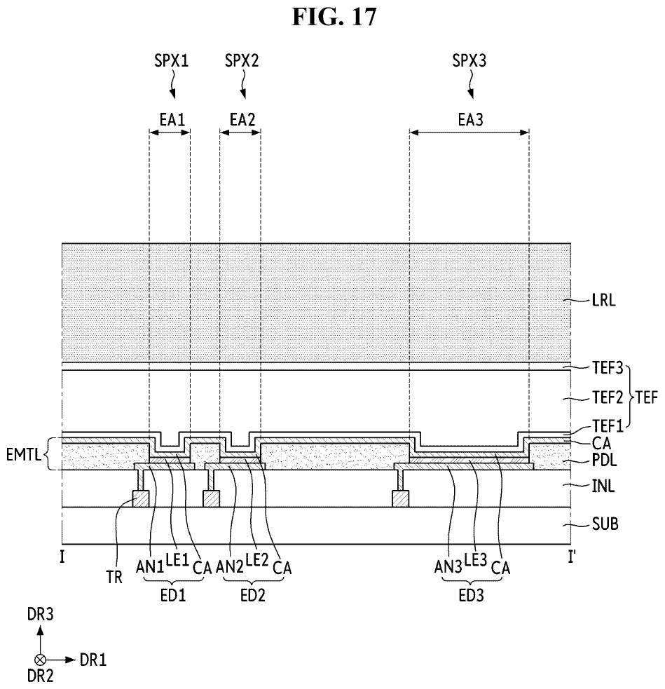

Subsequently, as illustrated in FIG. 17, the first refractive layer LRL is formed on the encapsulation layer TEF. For example, the first refractive layer LRL may be disposed on a third encapsulation inorganic layer TEF3 of the encapsulation layer TEF to overlap the first anode electrode AN1, the second anode electrode AN2, and the third anode electrode AN3. The first refractive layer LRL may include, for example, an organic material (or a transparent organic material). The first refractive layer LRL may have a refractive index ranging from 1.4 to 1.5. The first anode electrode AN1, the second anode electrode AN2, and the third anode electrode AN3 may be formed to contact a respective one of the transistors TR partially in the insulating layer INL and partially in the light emitting layer EMTL.

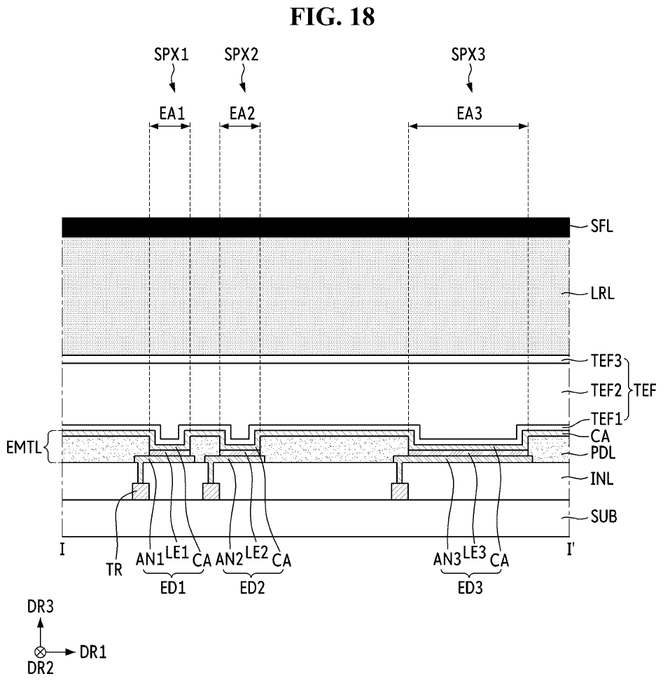

Next, as illustrated in FIG. 18, a sacrificial layer SFL is formed on the first refractive layer LRL. The sacrificial layer SFL may be disposed on the entire surface of the substrate SUB including the first refractive layer LRL. The sacrificial layer SFL may include, for example, a metal material. In an embodiment, the sacrificial layer SFL is made of a metal material including aluminum.

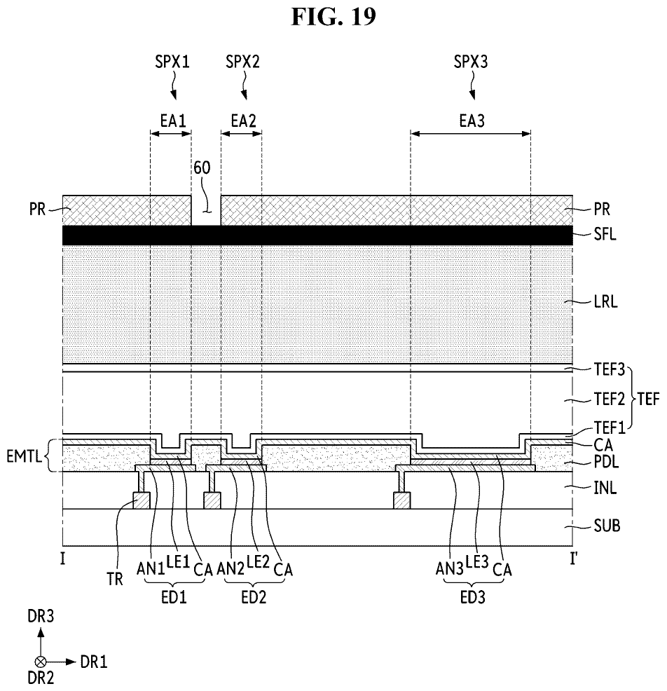

Subsequently, as illustrated in FIG. 19, a photoresist pattern PR is disposed on the sacrificial layer SFL. The photoresist pattern PR may be disposed on the sacrificial layer SFL to overlap the remaining portion of the sacrificial layer SFL except for a portion of the sacrificial layer SFL between the first emission area EA1 and the second emission area EA2. For example, the photoresist pattern PR may have a hole 60 that selectively exposes only a portion of the sacrificial layer SFL between the first emission area EA1 and the second emission area EA2.

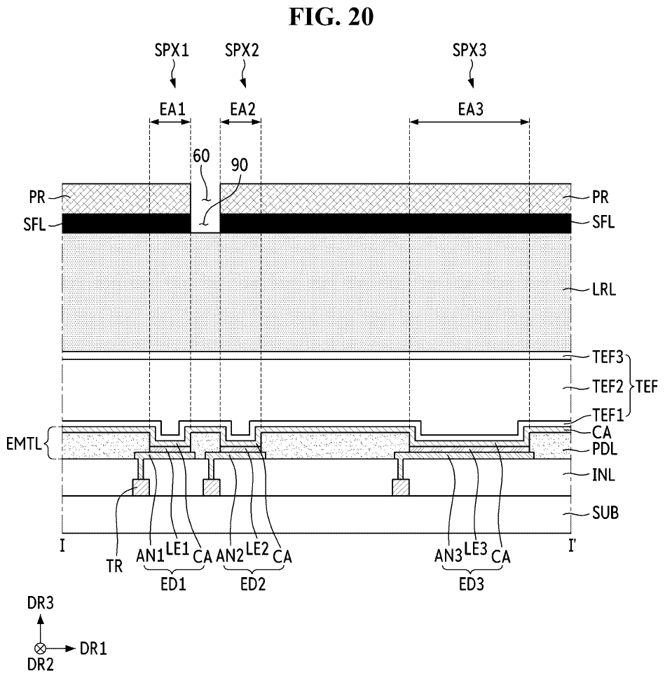

Thereafter, as illustrated in FIG. 20, the sacrificial layer SFL is patterned using the photoresist pattern PR as a mask. For example, the portion of the sacrificial layer SFL exposed through the hole 60 of the photoresist pattern PR may be selectively removed. Accordingly, the sacrificial layer SFL may overlap the remaining portion of the first refractive layer LRL except for a portion of the first refractive layer LRL between the first emission area EA1 and the second emission area EA2. For example, the sacrificial layer SFL may have a hole 90 that selectively exposes only the portion of the first refractive layer LRL between the first emission area EA1 and the second emission area EA2. Meanwhile, the sacrificial layer SFL may be removed by a wet etching method.

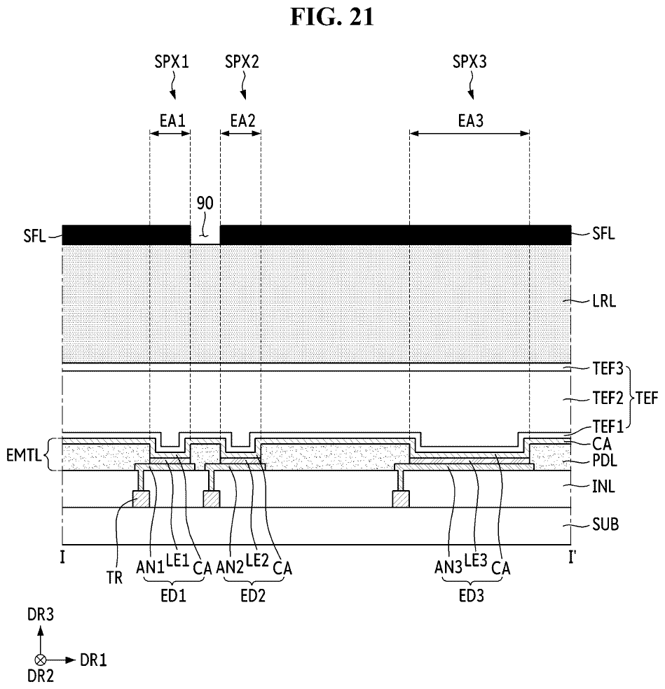

Subsequently, as illustrated in FIG. 21, the photoresist pattern PR is removed. When the photoresist pattern PR is removed, the sacrificial layer SFL (e.g., the sacrificial layer SFL having the hole 90) there below may be exposed.

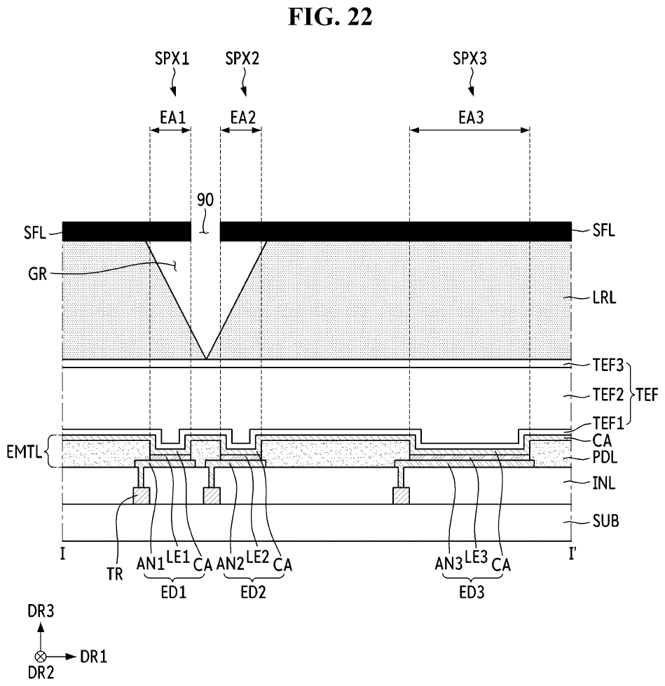

Next, as illustrated in FIG. 22, the first refractive layer LRL is patterned using the sacrificial layer SFL patterned to have the hole 90 as a mask (e.g., a hard mask). For example, a portion of the first refractive layer LRL exposed through the hole 90 in the sacrificial layer SFL may be selectively removed. Accordingly, the groove GR may be formed in the first refractive layer LRL. In an embodiment, the first refractive layer LRL is removed by dry etching. The first refractive layer LRL may be etched using isotropic etching as it approaches the sacrificial layer SFL, and may be etched using anisotropic etching as it moves away from the sacrificial layer SFL. Accordingly, the groove GR may have the shape of an inverted triangle with a width that gradually decreases toward the substrate SUB.

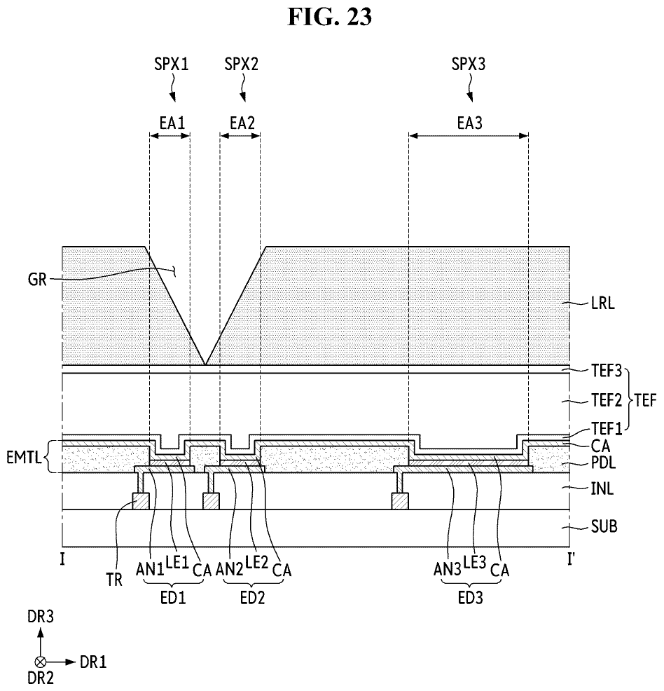

Subsequently, as illustrated in FIG. 23, the sacrificial layer SFL is removed. When the sacrificial layer SFL is removed, the first refractive layer LRL there below and the groove GR of the first refractive layer LRL may be exposed.

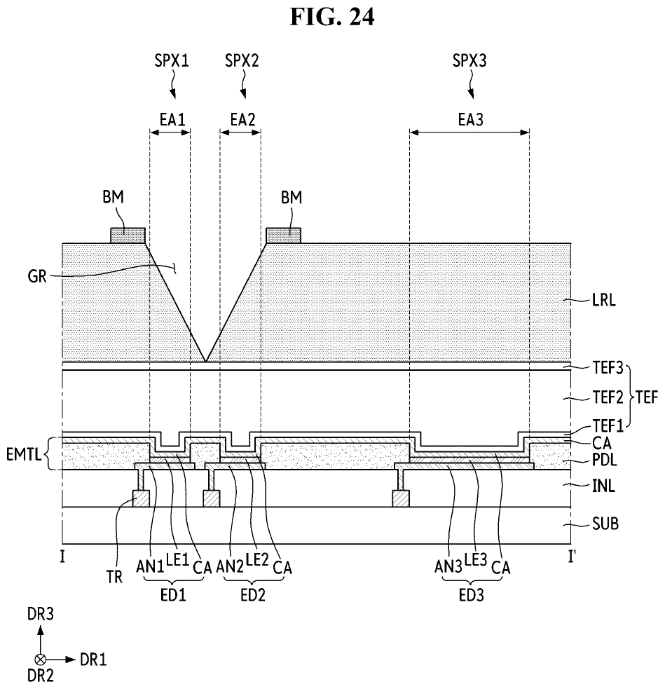

Next, as illustrated in FIG. 24, the light blocking layer BM is formed on the first refractive layer LRL. For example, the light blocking layer BM may be disposed on the first refractive layer LRL to be close to the groove GR of the first refractive layer LRL. For example, portions of the light blocking layer BM spaced apart from one another may be formed adjacent left and right edges of the groove GR where the groove GR is widest.

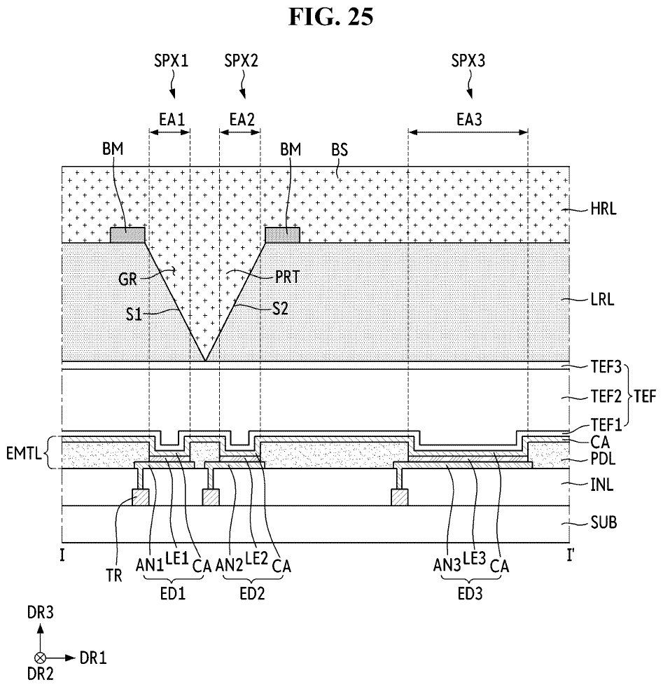

Thereafter, as illustrated in FIG. 25, the second refractive layer HRL is formed on the first refractive layer LRL and the light blocking layer BM. At this time, a portion of the second refractive layer HRL may be disposed in the groove GR of the first refractive layer LRL. For example, the second refractive layer HRL may include the protrusion PRT disposed in the groove GR of the first refractive layer LRL and the flat portion BS on the protrusion PRT. The protrusion PRT and the flat portion BS of the second refractive layer HRL may overlap the first anode electrode AN1 and the second anode electrode AN2, and the flat portion BS of the second refractive layer HRL may overlap the third anode electrode AN3. The second refractive layer HRL may include an organic material. For example, the second refractive layer HRL may include a transparent organic material. The second refractive layer HRL may have a refractive index ranging from 1.6 to 1.7.

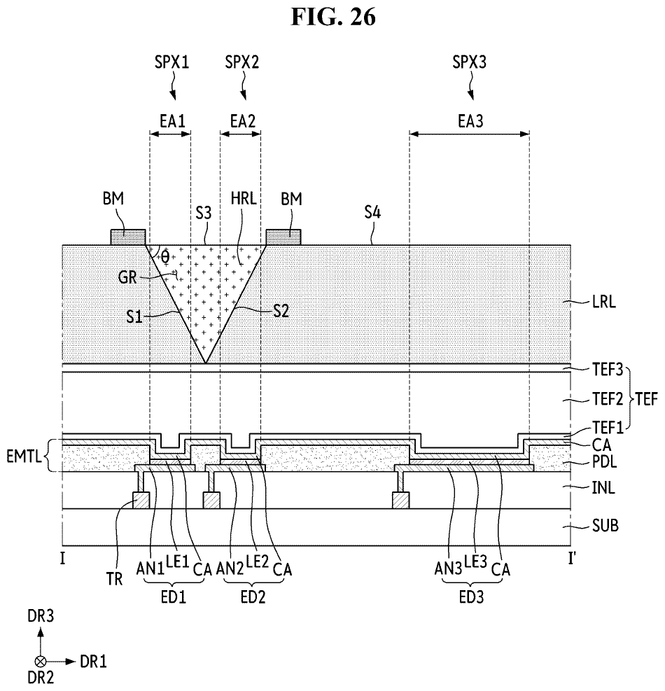

FIG. 26 is a cross-sectional view of the display device 100 according to an embodiment. For example, FIG. 26 may be a cross-sectional view of another embodiment, which is taken along line I-I′ of FIG. 3.

The display device 100 of FIG. 26 differs from the display device 100 of FIG. 4 primarily in the shape of the second refractive layer HRL, with the differences detailed as follows.

As illustrated in FIG. 26, the second refractive layer HRL has a width that gradually decreases along the direction toward the substrate SUB. For example, the second refractive layer HRL may have a cross-section of an inverted triangle.

The second refractive layer HRL may be disposed in the groove GR of the first refractive layer LRL. In an embodiment, the top surface of the second refractive layer HRL is positioned at the same height as a top surface S4 of the first refractive layer LRL. For example, the flat portion BS of the second refractive layer HRL shown in FIG. 25 is not present in FIG. 26.

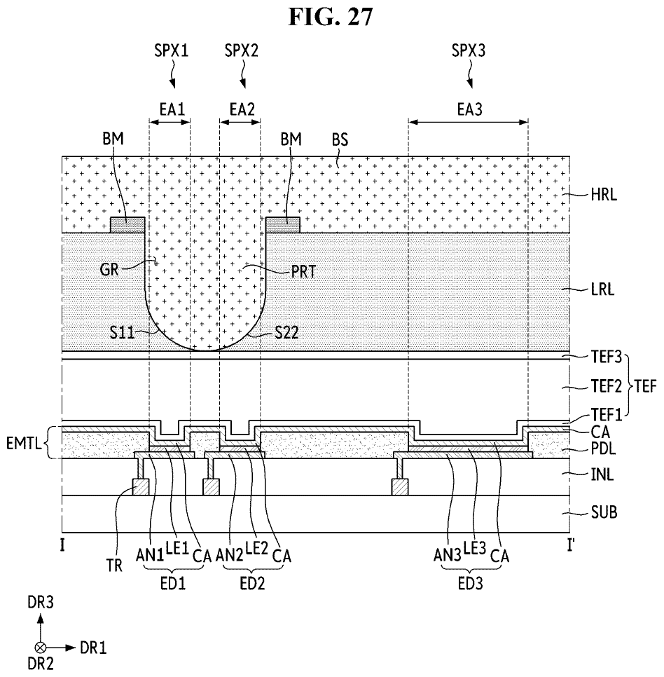

FIG. 27 is a cross-sectional view of the display device 100 according to an embodiment. For example, FIG. 27 may be a cross-sectional view of another embodiment, which is taken along line I-I′ of FIG. 3.

The display device 100 of FIG. 27 differs from the display device 100 of FIG. 4 primarily in the shape of the second refractive layer HRL, with the differences detailed as follows.

As illustrated in FIG. 27, the protrusion PRT of the second refractive layer HRL may have a rounded surface. For example, the protrusion PRT of the second refractive layer HRL may have a cross-section of a parabolic shape or a lens shape that is convex in the direction (e.g., in the third reverse direction) toward the substrate SUB. According to an embodiment, each of a first side surface S11 and a second side surface S22 of the protrusion PRT have a rounded or curved shape.

As illustrated in FIG. 27, the groove GR of the first refractive layer LRL may have a cross-section of a parabolic shape or a lens shape that is convex in the direction (e.g., in the third reverse direction) toward the substrate SUB. The flat portion BS of the second refractive layer HRL shown in FIG. 25 is present in FIG. 27.

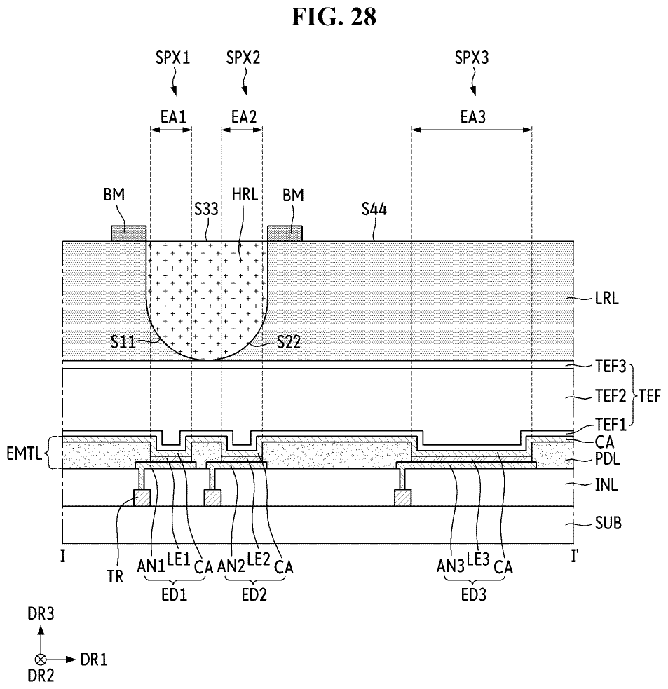

FIG. 28 is a cross-sectional view of the display device 100 according to an embodiment. For example, FIG. 28 is a cross-sectional view of another embodiment, which is taken along line I-I′ of FIG. 3.

The display device 100 of FIG. 28 differs from the display device 100 of FIG. 27 primarily in the shape of the second refractive layer HRL, with the differences detailed as follows.

As illustrated in FIG. 28, the second refractive layer HRL may have a rounded surface. For example, the second refractive layer HRL may have a cross-section of a parabolic shape or a lens shape that is convex in the direction (e.g., in the third reverse direction) toward the substrate SUB. According to an embodiment, each of the first side surface S11 and the second side surface S22 of the second refractive layer HRL have a rounded or curved shape.

The second refractive layer HRL may be disposed in the groove GR of the first refractive layer LRL. In an embodiment, a top surface S33 of the second refractive layer HRL is positioned at the same height as a top surface S44 of the first refractive layer LRL. For example, the flat portion BS of the second refractive layer HRL shown in FIG. 27 is not present in FIG. 28.

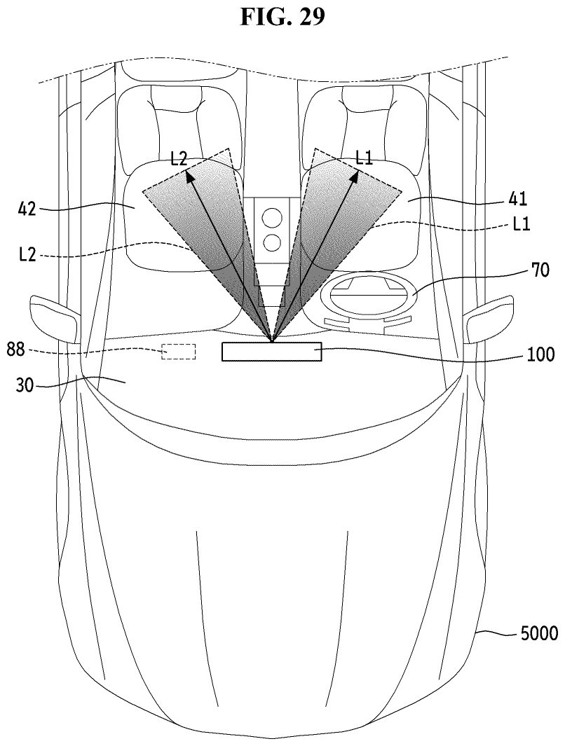

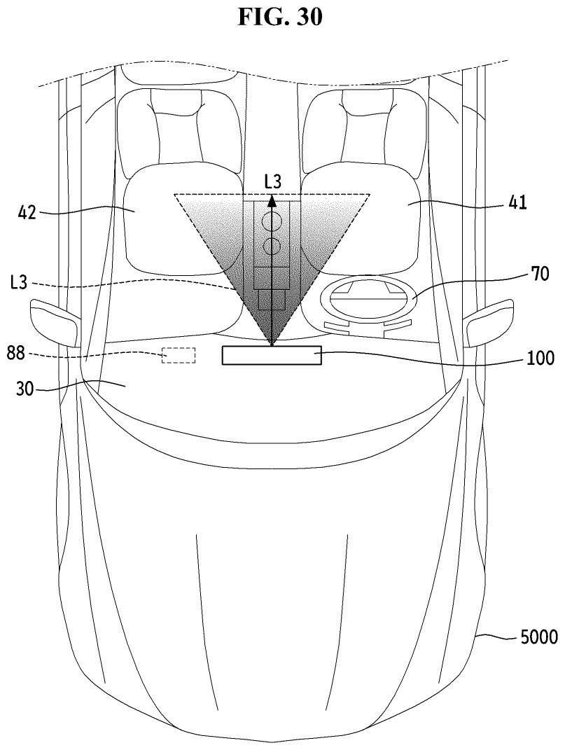

FIGS. 29 and 30 are schematic diagrams illustrating a vehicle including the display device 100 according to an embodiment.

The display device 100 according to an embodiment may be, for example, the display device 100 applied to the vehicle.

The vehicle may include a body forming an exterior of the vehicle and an interior space defined by the body. Additionally, the vehicle may further include a dashboard 30, a driver's seat 41, a passenger seat 42, and a steering wheel 70 disposed in the interior space of the vehicle. Additionally, the vehicle may further include a vehicle control unit 88 that collects vehicle information from the vehicle and controls the vehicle based on the collected vehicle information.

The display device 100 according to an embodiment may be provided in the interior space of the vehicle. For example, the display device 100 may be disposed on the dashboard 30. For example, the display device 100 may be disposed on the dashboard 30 between the driver's seat 41 and the passenger seat 42.

The display device 100 may provide vehicle information (e.g., a vehicle speed, driving information, maps, travel routes, and the like) and entertainment information (e.g., movies, games, and the like).

According to an embodiment, the display device 100 may be driven in either the first display mode or the second display mode based on whether the vehicle is driven. For example, when the vehicle is driven, the display device 100 may operate in the first display mode, whereas when the vehicle is stopped, the display device 100 may operate in the second display mode.

In an embodiment, the vehicle control unit 88 detects whether the vehicle is being driven. For example, when the vehicle is being driven, the vehicle control unit 88 may generate a driving signal, and when the vehicle is stopped, the vehicle control unit 88 may generate a stop signal. The driving signal and the stop signal from the vehicle control unit 88 may be provided to the display device 100. When the driving signal is provided to the display device 100 from the vehicle control unit 88, the display device 100 may operate in the first display mode as described above. On the other hand, when the stop signal is provided to the display device 100 from the vehicle control unit 88, the display device 100 may operate in the second display mode.

As illustrated in FIG. 29, when the display device 100 operates in the first display mode, the first light L1 from the first pixel PX1 may travel in the rightward direction (e.g., in the direction toward the driver's seat 41) of the display device 100, and the second light L2 from the first pixel PX1 may travel in the leftward direction (e.g., the direction toward the passenger seat 42). For example, when the display device 100 operates in the first display mode, the display device 100 may operate as in the first display mode period of FIG. 14 described above. The operation of the display device 100 in the first display mode may be substantially the same as the operation of the first pixel PX1 described with reference to FIGS. 13 and 14 described above. In an embodiment, an image based on the first light L1 may include vehicle information (or an image related to vehicle information), and an image based on the second light L2 may include entertainment information (or an image related to entertainment information).

As illustrated in FIG. 30, when the display device 100 operates in the second display mode, the third light L3 from the third pixel PX3 may travel in the front direction (e.g., the front direction including the direction toward the driver's seat 41 and the direction toward the passenger seat 42) of the display device 100. For example, when the display device 100 operates in the second display mode, the display device 100 may operate as in the second display mode period of FIG. 15 described above. The operation of the display device 100 in the second display mode may be substantially the same as the operation of the first pixel PX1 described with reference to FIGS. 13 and 15 described above. In an embodiment, an image based on the third light L3 may include device control information (or an image related to device control information). Here, the device control information may include various touch icons for controlling the vehicle's air conditioner, or the like.

In this way, when the vehicle is driven, the display device 100 may alternately provide different images toward the driver's seat 41 and the passenger seat 42, whereas when the vehicle is stopped, the display device 100 may provide the same image toward the driver's seat 41 and the passenger seat 42.

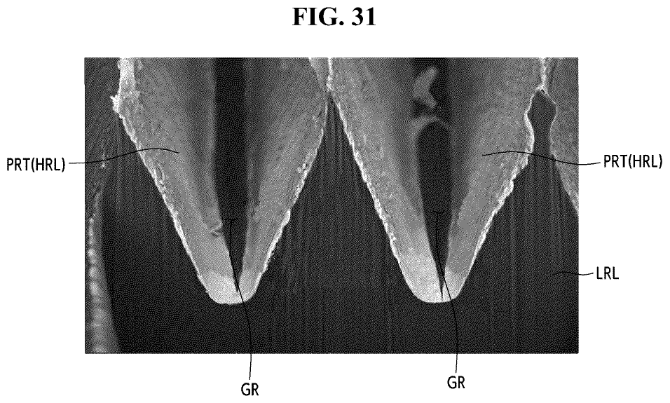

FIG. 31 shows a cross-sectional captured image of the display device 100 according to an embodiment. For example, FIG. 31 may be an image of a portion of the display device 100 captured using a scanning electron microscope.

As illustrated in FIG. 31, each of the groove GR of the first refractive layer LRL and the protrusion PRT of the second refractive layer HRL may have a cross-section in the shape of an inverted triangle.

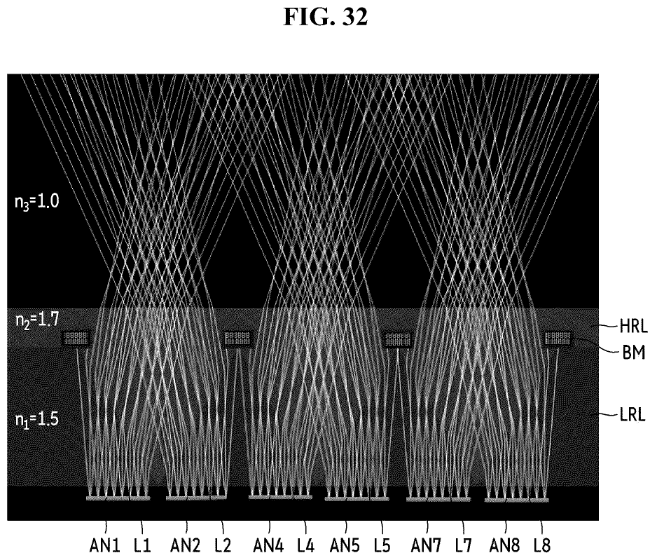

FIG. 32 illustrates a simulated experimental image illustrating the light path of the display device 100 according to an embodiment.

As illustrated in FIG. 32, the first light L1 emitted from the emission area corresponding to the first anode electrode AN1 may be refracted primarily while passing through the interface between the first refractive layer LRL and the second refractive layer HRL, and then be refracted secondarily while passing through the interface between the second refractive layer HRL and the air layer, and may travel in the rightward direction of the display device 100.

The second light L2 emitted from the emission area corresponding to the second anode electrode AN2 may be refracted primarily while passing through the interface between the first refractive layer LRL and the second refractive layer HRL, and then be refracted secondarily while passing through the interface between the second refractive layer HRL and the air layer, and may travel in the leftward direction of the display device 100.

The fourth light L4 emitted from the emission area corresponding to the fourth anode electrode AN4 may be refracted primarily while passing through the interface between the first refractive layer LRL and the second refractive layer HRL, and then be refracted secondarily while passing through the interface between the second refractive layer HRL and the air layer, and may travel in the rightward direction of the display device 100.

The fifth light L5 emitted from the emission area corresponding to the fifth anode electrode AN5 may be refracted primarily while passing through the interface between the first refractive layer LRL and the second refractive layer HRL, and then be refracted secondarily while passing through the interface between the second refractive layer HRL and the air layer, and may travel in the leftward direction of the display device 100.

The seventh light L7 emitted from the emission area corresponding to the seventh anode electrode AN7 may be refracted primarily while passing through the interface between the first refractive layer LRL and the second refractive layer HRL, and then be refracted secondarily while passing through the interface between the second refractive layer HRL and the air layer, and may travel in the rightward direction of the display device 100.

The eighth light L8 emitted from the emission area corresponding to the eighth anode electrode AN8 may be refracted primarily while passing through the interface between the first refractive layer LRL and the second refractive layer HRL, and then be refracted secondarily while passing through the interface between the second refractive layer HRL and the air layer, and may travel in the leftward direction of the display device 100.

In FIG. 32, the refractive index n₁ of the first refractive layer LRL is 1.5, the refractive index n₂ of the second refractive layer HRL is 1.7, and the refractive index n₃ of the air layer is 1.

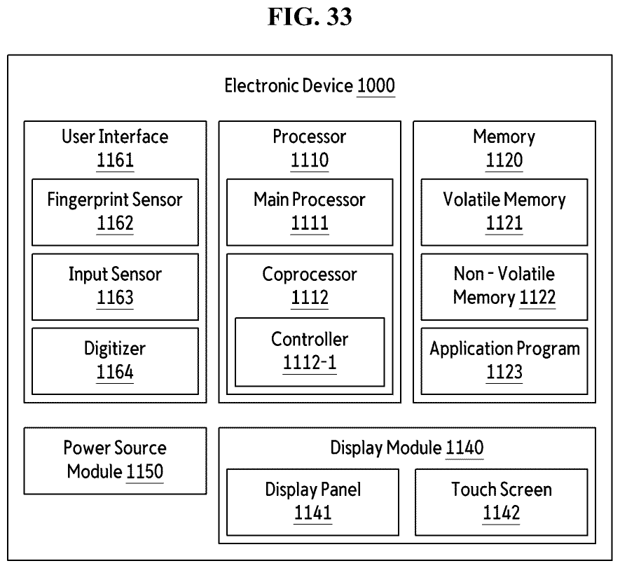

FIG. 33 is a diagram illustrating an electronic device according to an embodiment of the present invention. Referring to FIG. 33, the electronic device 1000 according to one embodiment of the present invention may output various information (e.g., images, text, music, etc.) through a display module 1140, which, for example, may correspond to the display device shown in FIG. 1. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 may be an AR/VR headset.

In some embodiments, the memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

It is to be understood by one of ordinary skill in the art to which the present disclosure belongs that the present disclosure may be implemented in other specific forms without changing the technical spirit or features of the present disclosure. Therefore, it is to be understood that the exemplary embodiments described above are illustrative rather than being restrictive in all aspects. Further, it is to be understood that all modifications and alterations derived from the claims and their equivalents fall within the scope of the present disclosure.

What is claimed is:

1. A display device comprising:
a substrate;
a first anode electrode, a second anode electrode, and a third anode electrode, the second anode electrode disposed adjacent to the first and third anode electrodes on the substrate;
a pixel defining layer disposed on the first anode electrode, the second anode electrode, and the third anode electrode, and defining a first emission area overlapping the first anode electrode, a second emission area overlapping the second anode electrode, and a third emission area overlapping the third anode electrode;
a first refractive layer having a groove, and disposed on the pixel defining layer to overlap the first emission area, the second emission area, and the third emission area; and
a second refractive layer disposed in the groove of the first refractive layer, and having a refractive index different from that of the first refractive layer,
wherein the groove overlaps the first emission area and the second emission area,
the second refractive layer disposed in the groove overlaps the first emission area and the second emission area, and
a width of the groove and the second refractive layer in the groove gradually decreases toward the substrate.

2. The display device of claim 1, wherein the refractive index of the second refractive layer is greater than the refractive index of the first refractive layer.

3. The display device of claim 1, wherein a difference between the refractive index of the first refractive layer and the refractive index of the second refractive layer is greater than or equal to 0.1.

4. The display device of claim 1, wherein the refractive index of the first refractive layer ranges from 1.4 to 1.5, and
the refractive index of the second refractive layer ranged from 1.6 to 1.7.

5. The display device of claim 1, wherein the groove and the second refractive layer in the groove have a same shape.

6. The display device of claim 1, wherein the groove and the second refractive layer in the groove each have a cross-section that is either: (i) triangular and pointed toward the substrate, (ii) parabolic and convex toward the substrate, or (iii) lens-shape and convex toward the substrate.

7. The display device of claim 1, wherein the first refractive layer in the groove comprises:
a first side surface facing one inner wall of the groove; and
a second side surface facing the other inner wall of the groove.

8. The display device of claim 7, wherein a distance between the first side surface and the second side surface gradually decreases along a direction toward the substrate.

9. The display device of claim 8, wherein the first side surface of the second refractive layer overlaps the first emission area, and
the second side surface of the second refractive layer overlaps the second emission area.

10. The display device of claim 8, wherein an angle between a first side surface of the second refractive layer and a top surface of the second refractive layer is an acute angle.

11. The display device of claim 1, wherein the second refractive layer comprises:
a flat portion disposed on the first refractive layer; and
a protrusion extending from the flat portion and disposed in the groove of the first refractive layer.

12. The display device of claim 11, wherein the flat portion of the second refractive layer overlaps the first emission area, the second emission area, and the third emission area.

13. The display device of claim 11, wherein the protrusion of the second refractive layer overlaps the first emission area and the second emission area.

14. The display device of claim 13, wherein the protrusion of the second refractive layer does not overlap the third emission area.

15. The display device of claim 1, further comprising a light blocking layer disposed on the first refractive layer.

16. The display device of claim 15, wherein the light blocking layer is disposed on the first refractive layer and positioned adjacent to the groove.

17. The display device of claim 15, wherein in a plan view, the light blocking layer is disposed between the second emission area and the third emission area.

18. The display device of claim 15, wherein in a plan view, the first emission area and the second emission area are disposed between two adjacent light blocking layers.

19. A vehicle comprising:
a dashboard;
a driver seat and a passenger seat disposed adjacent to the dashboard; and
a display device disposed on the dashboard,
wherein the display device comprises:
a substrate;
a first anode electrode, a second anode electrode, and a third anode electrode, the second anode electrode disposed adjacent to the first and third anode electrodes;
a pixel defining layer disposed on the first anode electrode, the second anode electrode, and the third anode electrode, and defining a first emission area overlapping the first anode electrode, a second emission area overlapping the second anode electrode, and a third emission area overlapping the third anode electrode;
a first light emitting layer disposed on the first anode electrode;
a second light emitting layer disposed on the second anode electrode;
a third light emitting layer disposed on the third anode electrode;
a cathode electrode disposed on the first light emitting layer, the second light emitting layer, and the third light emitting layer;
a first light emitting element comprising the first anode electrode, the first light emitting layer, and the cathode electrode;
a second light emitting element comprising the second anode electrode, the second light emitting layer, and the cathode electrode; and
a third light emitting element comprising the third anode electrode, the third light emitting layer, and the cathode electrode,
wherein the display device is configured to control a light emission direction of the first light emitting element, the second light emitting element and the third light emitting element, based on whether the vehicle is being driven.

20. An electronic device, comprising:
a processor;
a memory having stored application programs for execution by the processor;
a display device, comprising:
a display panel comprising:
a first anode electrode, a second anode electrode, and a third anode electrode, the second anode electrode disposed adjacent to the first and third anode electrodes;
a pixel defining layer disposed over the first, second, and third anode electrodes, defining a first emission area overlapping the first anode electrode, a second emission area overlapping the second anode electrode, and a third emission area overlapping the third anode electrode;
a first refractive layer having a groove and disposed over the pixel defining layer; and
a second refractive layer disposed within the groove of the first refractive layer, wherein the second refractive layer has a refractive index different from that of the first refractive layer, and both the groove and the second refractive layer tapering in width; and
a user interface configured to sense user input via touch or cursor select of an icon presented on the display panel, wherein the processor is caused to execute one or more of the stored application programs upon receipt of the user input.
